(19) United States
(12) Patent Application Publication
(10) Pub. No.: US 2026/0054980 A1
(43) Pub. Date: Feb. 26, 2026

(54) METHOD OF MANUFACTURING A LAYERED STRUCTURE FOR A MEMS APPARATUS AND MEMS APPARATUS HAVING SUCH A LAYERED STRUCTURE

(71) Applicant: OQMENTED GMBH, Itzehoe (DE)

(72) Inventors: Frank SENGER, Hadenfeld (DE); Stephan MARAUSKA, Kaltenkirchen (DE); Ulrich HOFMANN, Itzehoe (DE)

(21) Appl. No.: 18/994,529

(22) PCT Filed: Jul. 12, 2023
(86) PCT No.: PCT/EP2023/069360

§ 371 Date: Jan. 14, 2025

(30) Foreign Application Priority Data
Jul. 14, 2022 (DE) 10 2022 117 679.7

(51) Int. Cl. B81B 3/00; B81C 1/00; G02B 26/08

(52) U.S. Cl. CPC B81B 3/0045; B81C 1/00515; G02B 26/0858; B81B 2201/042; B81B 2203/0163; B81C 2201/0116; B81C 2201/0132

(57) ABSTRACT

The present disclosure relates to a method of manufacturing a layered structure for a MEMS apparatus, a layered structure manufactured by the method, and a MEMS apparatus 200 (300, 400, 500) comprising the layered structure. For the layered structure, a high-temperature curing step is provided in the manufacturing process, for example, after structuring the functional layer 3. The structured regions and trenches of the functional layer 3 and in particular the spring structure formed in the functional layer 3 have smoothened side walls and/or rounded corners in regions 3a after the curing step, so that their fracture limits can thus be increased and early fractures of the functional layer 3 during operation of the MEMS apparatus 200 (300, 400, 500) can be avoided.

### DESCRIPTION

The present disclosure relates to a method of manufacturing a layered structure for a MEMS apparatus, a layered structure manufactured by the method, and a MEMS apparatus comprising the layered structure.

### BACKGROUND

A generic method for manufacturing a layered structure for a MEMS apparatus and a generic MEMS apparatus comprising the layered structure are known, for example, from US 2009/0185253 A1.

In the processes commonly used in the prior art, for structuring a mechanically effective functional layer (often referred to as Device Layer) of the layer structure of the MEMS (micro-electro-mechanical system), so-called high-rate etching or Deep Reactive Ion Etching (DRIE) is typically used to form the deep trenches in the functional layer, in particular, for example, to form or carve out the movable or oscillating bodies and the corresponding spring structure that holds the movable or oscillating bodies in the functional layer. In the field of MEMS apparatus manufacturing, this is sometimes referred to as the Bosch process, as it is based on a process developed by Bosch in the 1990s.

When using such dry etching processes for structuring the movable or oscillating bodies and the spring structure that holds the movable or oscillating bodies, damage or unevenness occurs in the functional layer on the etched side walls in the structured regions of the functional layer due to the process, in particular so-called scallops (i.e. e.g. surface corrugations, surface nose structures, etc.). In addition, the mask used for structuring causes a direct transfer into the material of the functional layer (usually silicon) and therefore the manufactured structures typically exhibit right-angled corners.

High stress can occur in the MEMS structure during resonant oscillations at the locations of surface damage (e.g. so-called scallops, notches, sidewall breakthroughs or atomic defects, etc.) on the side walls of the trenches of the structured functional layer and at the formed right-angled corners in the structure, which can lead to premature fractures in structures of the functional layer.

In view of the disadvantages described above, it is an object of the present disclosure, based on the prior art described above, to provide an improved method for manufacturing a layered structure for a MEMS apparatus, in particular in order to provide a MEMS apparatus comprising the layered structure with higher mechanical breaking limits of the mechanically acting components of the layered structure and/or lower susceptibility to breakage.

### SUMMARY

The present disclosure relates to a method for manufacturing a layered structure for a MEMS apparatus, a layered structure manufactured by the method, and a MEMS apparatus comprising the layered structure, in particular a vacuum-packed MEMS mirror device.

In particular, a method for manufacturing a layered structure for a MEMS apparatus and a layered structure manufactured by the method according to the independent claims as well as a MEMS apparatus comprising the layered structure, in particular a vacuum-packed MEMS mirror device, are proposed for solving the above-mentioned object. The dependent claims relate to some exemplary preferred exemplary embodiments.

According to a first aspect, in some exemplary embodiments, a method for manufacturing a layered structure for a MEMS apparatus, in particular a MEMS mirror device or a vacuum-packed MEMS mirror device, is proposed, the method comprising: providing a layered structure which comprises a substrate layer and/or a functional layer; applying a piezoelectric layer, e.g. on and/or above the functional layer, in particular on a side opposite the substrate layer of the functional layer, i.e. in particular preferably on a side of the functional layer opposite the substrate layer; and/or structuring the piezoelectric layer, e.g. on and/or above the functional layer, in particular on a side of the functional layer opposite the substrate layer, e.g. on and/or over the functional layer, in particular on a side of the functional layer opposite the substrate layer, i.e. in particular preferably on a side of the functional layer opposite the substrate layer; and/or structuring the piezoelectric layer, in particular for forming structured regions of the piezoelectric layer.

In some exemplary embodiments, an electrode layer (bottom electrode layer) may be provided between the functional layer and the piezoelectric layer, which electrode layer may form a bottom electrode, e.g. of metal (e.g. molybdenum), electrically contacting the piezoelectric layer from below. In exemplary embodiments, the method may comprise applying an electrode layer to the functional layer before applying the piezoelectric layer, wherein the piezoelectric layer may be applied to the electrode layer. In some exemplary embodiments, the functional layer (e.g. in doped regions) can be at least partially electrically conductive, so that the functional layer can at least partially provide a bottom electrode for the piezoelectric layer.

In some preferred exemplary embodiments, the method may comprise structuring the functional layer, in particular preferably to form structured or structured regions and/or trenches (i.e., for example, trenches surrounding the structured regions) in the functional layer, in particular preferably optionally by high rate etching or Deep Reactive Ion Etching (DRIE for short).

In some preferred exemplary embodiments, the method may preferably further comprise curing structured regions of the functional layer and/or trenches in the structured regions (e.g., in particular preferably for at least partially smoothing sidewalls of the trenches in the functional layer and/or for rounding corners of the trenches in the functional layer), preferably at temperatures substantially greater than or equal to 700° C.

In some preferred exemplary embodiments, the curing of structured regions of the functional layer may be performed to at least partially smooth sidewalls of the trenches in the functional layer and/or to round corners of the trenches in the functional layer.

Smoothing of the side walls of the trenches in the structured regions of the functional layer may mean in particular that the unevenness and/or surface effects or defects which occur on the side walls during the structuring of the functional layer as a result of the process are reduced, so that, relative to the state of the side wall surfaces after the structuring of the functional layer, smoother side wall surfaces are provided after curing, possibly even achieving completely smooth and/or crystal defect-free side walls. Preferably, the sidewall surfaces can have a roughness substantially less than or equal to 50 nm after curing, preferably in particular a roughness substantially less than or equal to 30 nm and particularly preferably in particular a roughness substantially less than or equal to 10 nm.

In some preferred exemplary embodiments, the curing of structured regions of the functional layer may preferably be carried out at temperatures substantially greater than or equal to 800° C. In some preferred exemplary embodiments, the curing of structured regions of the functional layer can be carried out at temperatures substantially less than or equal to 1400° C., in particular preferably at temperatures substantially less than or equal to 1350° C., in particular preferably at temperatures substantially less than or equal to 1250° C. or substantially less than or equal to 1200° C.

Preferably, in some exemplary embodiments, the temperatures in the curing step or preferably in the entire manufacturing process should not exceed 1400° C., more preferably 1350° C., as the melting point of silicon is about 1410° C., since the substrate layer and/or the functional layer may typically comprise silicon.

Here, the integration of a high-temperature curing step according to some exemplary embodiments (e.g. by hydrogen annealing and/or by a sacrificial oxidation) makes it conveniently possible to at least partially smooth any structured or depth-etched sidewalls of the structured functional layer in order to smooth defects and roughness (e.g. surface scallops, surface notches, sidewall breakthroughs or atomic defects, etc.) arising during the etching process (e.g. DRIE) on the surface of the sidewalls and/or also to round off any right-angled corners created during etching.

According to exemplary embodiments, this conveniently can lead to a significantly increased stability or improved fracture stability of the movable elements of the layered structure and/or the MEMS apparatus comprising such a layered structure with increased fracture limits, and, in particular, of the spring structure formed from the functional layer with increased fracture limits, whereby overall premature fractures can be avoided. Compared to prior art methods without a curing step, the fracture limits of the moving or oscillating parts of the functional layer, or, in particular, of the spring structure formed in the functional layer, can be at least doubled or even increased fivefold or tenfold according to some exemplary embodiments involving a curing step. Compared to the state of the art, i.e. when components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be significantly reduced in particular for the spring structure and, in particular, larger deflection angles or deflection amplitudes can also be made possible, even though fractures of the deflection structures or the spring structure would already occur at such higher deflection amplitudes or deflection angles in components manufactured according to the prior art.

In some preferred exemplary embodiments, curing of structured regions of the functional layer may preferably comprise hydrogen annealing, in particular preferably at temperatures substantially greater than or equal to 900° C. and/or substantially less than or equal to 1350° C., more preferably at temperatures substantially greater than or equal to 1000° C. and/or substantially less than or equal to 1250° C. (or exemplarily substantially less than or equal to 1200° C.) In some preferred exemplary embodiments, curing of structured regions of the functional layer may preferably comprise oxidizing sidewalls of the trenches in the functional layer, preferably at temperatures substantially greater than or equal to 700° C., in particular at substantially greater than or equal to 800° C., and/or at substantially less than or equal to 1250° C. (or exemplarily substantially less than or equal to 1200° C.).

In some preferred exemplary embodiments, curing of structured regions of the functional layer may preferably further comprise removing an oxidation layer formed on sidewalls of the trenches in the functional layer, e.g. in particular removing an oxidation layer formed on sidewalls of the trenches in the functional layer, in particular preferably by etching (e.g. etching of the sacrificial oxidation layer)

In some preferred exemplary embodiments, the method may preferably comprise: applying an electrode layer preferably after curing of structured regions of the functional layer to form an electrode structure for the structured regions of the piezoelectric layer and/or to form a mirror and/or a mirror layer on one or more structured regions of the functional layer.

In some exemplary embodiments, the electrode layer can serve as a top electrode of the piezoelectric layer. In some exemplary embodiments, the electrode layer can also be used as a rewiring (routing) and/or as a bond pad (e.g. for electrical connection to a bottom electrode).

In some preferred exemplary embodiments, the method may preferably comprise: applying a high-temperature-stable electrode layer preferably prior to curing of the structured regions of the functional layer to form an electrode structure for the structured regions of the piezoelectric layer.

In some exemplary embodiments, the high-temperature-stable electrode layer can serve as a top electrode of the piezoelectric layer. In some exemplary embodiments, the high-temperature-stable electrode layer can also be used as a routing and/or as a bond pad (e.g. for electrical connection to a bottom electrode).

In some preferred exemplary embodiments, the material of the electrode layer and/or the high-temperature-stable electrode layer may comprise an electrically conductive doped silicon, in particular doped polycrystalline silicon.

In some preferred exemplary embodiments, the material of the electrode layer or high-temperature-stable electrode layer can comprise a high-temperature-stable metal, a high-temperature-stable metal alloy or metal compound, in particular preferably a refractory metal, in particular preferably platinum, molybdenum (melting point at approx. 2623° C.) and/or a high-temperature-stable molybdenum alloy and/or molybdenum compound, tungsten (melting point at approx. 3422° C.) and/or a high-temperature-stable tungsten alloy and/or tungsten compound, in particular tungsten titanium and/or tungsten carbide.

In some preferred exemplary embodiments, the method may preferably further comprise: applying a further layer, preferably after curing structured regions of the functional layer, to form a mirror and/or a mirror layer on one or more structured regions of the functional layer.

In some preferred exemplary embodiments, the method may preferably further comprise: applying a dielectric layer, in particular to at least the structured regions of the piezoelectric layer. In some preferred exemplary embodiments, the application of the dielectric layer may occur after application and/or structuring of the piezoelectric layer. In some exemplary embodiments, the dielectric layer may preferably be applied prior to the curing of structured regions of the functional layer. In some exemplary embodiments, the dielectric layer can also be applied after the structured regions of the functional layer have been cured.

In some preferred exemplary embodiments, the structured regions of the piezoelectric layer may preferably be or may be encapsulated between the functional layer and the dielectric layer applied to the structured regions of the piezoelectric layer, particularly preferably when the application of the dielectric layer occurs prior to the curing of structured regions of the functional layer.

Conveniently, it was recognized here that the provision of a layer structure according to some exemplary embodiments with structured regions of the piezoelectric layer encapsulated under a high-temperature-stable layer (e.g. under a dielectric layer) can enable the integration of one or more high-temperature curing steps (such as hydrogen annealing of deep-etched surfaces, e.g. at approx. 1000° C.-1250° C., and/or sacrificial oxidation, e.g. at approx. 800° C.-1250° C., with etching back of the sacrificial oxide layer), in particular also with less high-temperature-stable piezoelectric materials and in particular also with less chemically resistant piezoelectric materials, which can be protected by encapsulation from aggressive media, such as oxygen (e.g. in a curing step with sacrificial oxidation) and/or hydrogen (e.g. in a curing step with hydrogen annealing).

Consequently, in some preferred exemplary embodiments, the method may preferably further comprise: applying a dielectric layer at least to the structured regions of the piezoelectric layer, prior to curing structured regions of the functional layer and in particular preferably prior to applying an electrode layer, preferably such that the structured regions of the piezoelectric layer are encapsulated between the functional layer and the dielectric layer applied to the structured regions of the piezoelectric layer.

Alternatively or additionally, in some exemplary embodiments, the piezoelectric layer can also be protected by encapsulation under the electrode layer of high-temperature-stable material or high-temperature-stable metal (see some exemplary embodiments with exemplary high-temperature-stable electrode layer).

In some preferred exemplary embodiments, the structured regions of the piezoelectric layer may preferably be or become encapsulated between the functional layer and the high-temperature-stable electrode layer (optionally with intervening or regionally intervening dielectric layer) applied to the structured regions of the piezoelectric layer, particularly preferably when the application of the high-temperature-stable electrode layer occurs prior to the curing of structured regions of the functional layer.

Accordingly, in some preferred exemplary embodiments, the method may preferably further comprise: applying and/or structuring the high-temperature-stable electrode layer, in particular preferably before curing structured regions of the functional layer, preferably such that the structured regions of the piezoelectric layer are encapsulated between the functional layer and the applied high-temperature-stable electrode layer (optionally with interposed or regionally interposed dielectric layer).

In some preferred exemplary embodiments, the method may preferably further comprise: structuring and/or opening regions of the dielectric layer preferably during or prior to structuring the functional layer, in particular preferably such that the structured regions of the piezoelectric layer remain encapsulated between the functional layer and the dielectric layer deposited on the structured regions of the piezoelectric layer.

In some exemplary embodiments in which the piezoelectric layer is encapsulated, the material of the piezoelectric layer may comprise a ferro- and/or piezoelectric material, in particular preferably aluminum nitride (AlN), aluminum scandium nitride (AlScN), lead zirconate titanate (PZT) and/or niobium doped PZT (PZT-Nb).

In some preferred exemplary embodiments, the method may preferably further comprise: applying a dielectric layer to at least the structured regions of the piezoelectric layer after curing of structured regions of the functional layer. In some preferred exemplary embodiments, the method may preferably further comprise: structuring and/or opening regions of the dielectric layer.

In some exemplary embodiments, the material of the piezoelectric layer may comprise a high-temperature-stable ferroelectric and/or piezoelectric material, in particular preferably aluminum nitride (AlN) and/or aluminum scandium nitride (AlScN).

In some preferred exemplary embodiments, the structured portions of the functional layer may comprise one or more movable elements preferably formed in the functional layer and/or a spring structure preferably formed in the functional layer, wherein the spring structure may particularly preferably hold the one or more movable elements.

In some preferred exemplary embodiments, the one or more movable elements of the structured regions of the functional layer may comprise a mirror support element, wherein a mirror may preferably be arranged on the mirror support element.

In some preferred exemplary embodiments, the spring structure of the structured regions of the functional layer can hold the mirror support element with a mirror. The spring structure in the functional layer can preferably be designed in such a way that the mirror support element with the mirror is held so that it can oscillate about one or two axes, in particular oscillation and/or torsion axes, in particular preferably for a two-dimensional Lissajous scanning movement of the mirror support element with the mirror.

In some exemplary embodiments, the spring structure may comprise springs, in particular preferably bending and/or torsion springs, which are preferably designed to hold the mirror support element in such a way that the mirror support element can perform an oscillating rotational movement about the respective oscillating and/or torsional axis (e.g. torsional oscillations).

In some preferred exemplary embodiments, structuring of the functional layer may comprise high rate etching and/or reactive ion depth etching.

According to a second aspect, in some exemplary embodiments, a layered structure manufactured by the method according to at least one of the preceding aspects and exemplary embodiments is further proposed.

In some preferred exemplary embodiments, the layered structure may comprise: a substrate layer, a structured functional layer, a structured piezoelectric layer preferably on a side of the functional layer opposite to the substrate layer, i.e. in particular on a side of the functional layer opposite to the substrate layer, and/or a dielectric layer preferably at least on the structured regions of the piezoelectric layer. In some preferred exemplary embodiments, the structured regions of the piezoelectric layer may preferably be encapsulated between the functional layer and the dielectric layer preferably applied to the structured regions of the piezoelectric layer.

In some exemplary embodiments, an electrode layer can be provided between the functional layer and the piezoelectric layer, which electrode layer can form a bottom electrode, e.g. made of metal (e.g. molybdenum), which electrically contacts the piezoelectric layer from below.

In some preferred exemplary embodiments, trenches in the functional layer may preferably be cured in structured regions of the functional layer, in particular on side walls of the trenches and in particular preferably having smoothened side walls and/or rounded corners.

In some preferred exemplary embodiments, trenches in the functional layer in structured regions of the functional layer may preferably have smoothened sidewalls and/or rounded corners and/or the sidewalls and/or structured regions of the functional layer may have rounded corners.

In some preferred exemplary embodiments, a surface roughness of sidewalls of the trenches in the functional layer in structured regions of the functional layer may be substantially less than or equal to 50 nm, in particular substantially less than or equal to 30 nm, more preferably less than or equal to 10 nm.

According to a third aspect, in some exemplary embodiments, there is further proposed a MEMS apparatus, in particular a MEMS mirror device or vacuum-packed MEMS mirror device, comprising a layered structure manufactured by the method according to at least one of the preceding aspects and exemplary embodiments.

Further aspects and examples of some exemplary embodiments as well as advantages and some more specific exemplary embodiments of the aspects and features described above can also be found in the following descriptions and explanations of the attached drawings, which are not to be understood as limiting in any way.

### BRIEF DESCRIPTION OF THE DRAWINGS

FIG. 1 shows an exemplary flow chart of a process for manufacturing a layered structure for a MEMS apparatus according to a background example,

FIGS. 2A-2C show exemplary sectional views of the layer structure during the manufacturing process according to an exemplary manufacturing sequence based on the process according to FIG. 1,

FIG. 3 shows an exemplary flowchart of a process for manufacturing a layered structure for a MEMS apparatus according to some exemplary embodiments of the present disclosure,

FIGS. 4A-4B show exemplary sectional views of the layer structure during the manufacturing process according to an exemplary manufacturing sequence based on the process according to FIG. 3,

FIG. 5 shows an exemplary sectional view of a MEMS apparatus manufactured according to the exemplary manufacturing sequence of FIGS. 4A-4B,

FIGS. 6A-6B show exemplary sectional views of the layer structure during the manufacturing process according to a further exemplary manufacturing sequence based on the process according to FIG. 3,

FIG. 7 shows an exemplary sectional view of a MEMS apparatus manufactured according to the exemplary manufacturing sequence of FIGS. 6A-6B,

FIG. 8 shows an exemplary flowchart of a method of manufacturing a layered structure for a MEMS apparatus according to some further exemplary embodiments of the present disclosure,

FIGS. 9A-9B show exemplary sectional views of the layer structure during the manufacturing process according to an exemplary manufacturing sequence based on the process according to FIG. 8,

FIG. 10 shows an exemplary sectional view of a MEMS apparatus manufactured according to the exemplary manufacturing sequence of FIGS. 9A-9B,

FIG. 11 shows an exemplary flowchart of a process for manufacturing a layered structure for a MEMS apparatus according to some further exemplary embodiments of the present disclosure,

FIGS. 12A-12B show exemplary sectional views of the layer structure during the manufacturing process according to an exemplary manufacturing sequence based on the process according to FIG. 11, and

FIG. 13 shows an exemplary sectional view of a MEMS apparatus manufactured according to the exemplary manufacturing sequence of FIGS. 12A-12C.

### DETAILED DESCRIPTION OF THE DRAWINGS AND SOME PREFERRED EXAMPLES

In the following, examples or some exemplary embodiments of the present disclosure are described in detail with reference to the accompanying drawings. Identical or similar elements in the drawings may be designated with the same reference signs, but sometimes also with different reference signs.

However, it should be emphasized that the subjects of the present disclosure are in no way limited or restricted to the exemplary embodiments described below and their exemplary features, but further include modifications of the exemplary embodiments, in particular those encompassed by modifications of the features of the described examples or by combining individual or several of the features of the described examples within the scope of protection of the independent claims.

With regard to the terminology used in the present disclosure, it should be noted that the following refers in part to “high-temperature-stable” materials or to a material property “high-temperature-stable”. For the purposes of the present disclosure, the term “high-temperature-stable” material or the material property “high-temperature-stable” is intended to mean that such materials withstand temperatures greater than or equal to substantially 1200° C., in particular preferably greater than or equal to substantially 1250° C. or substantially greater than 1250° C., and in particular have a melting point greater than or equal to substantially 1200° C., in particular greater than or equal to substantially 1250° C. or substantially greater than 1250° C., in particular preferably greater than or equal to substantially 1400° C.

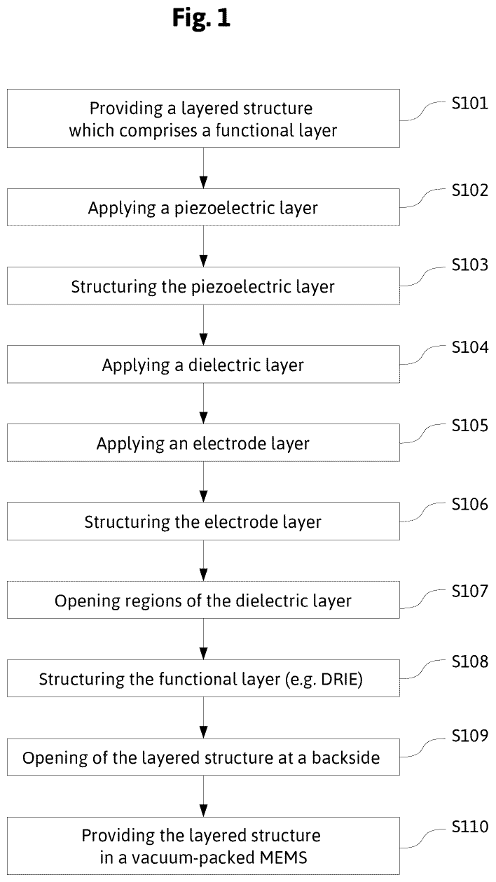

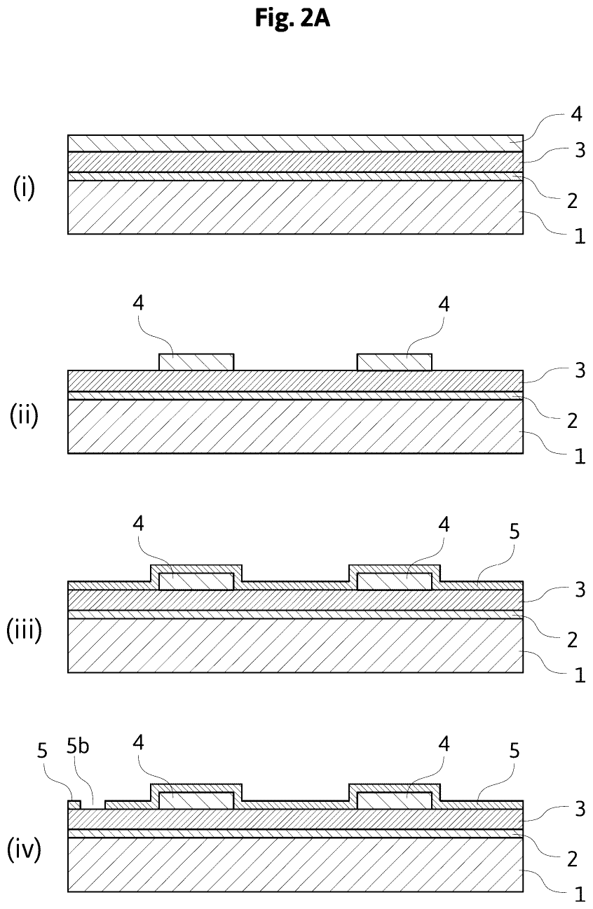

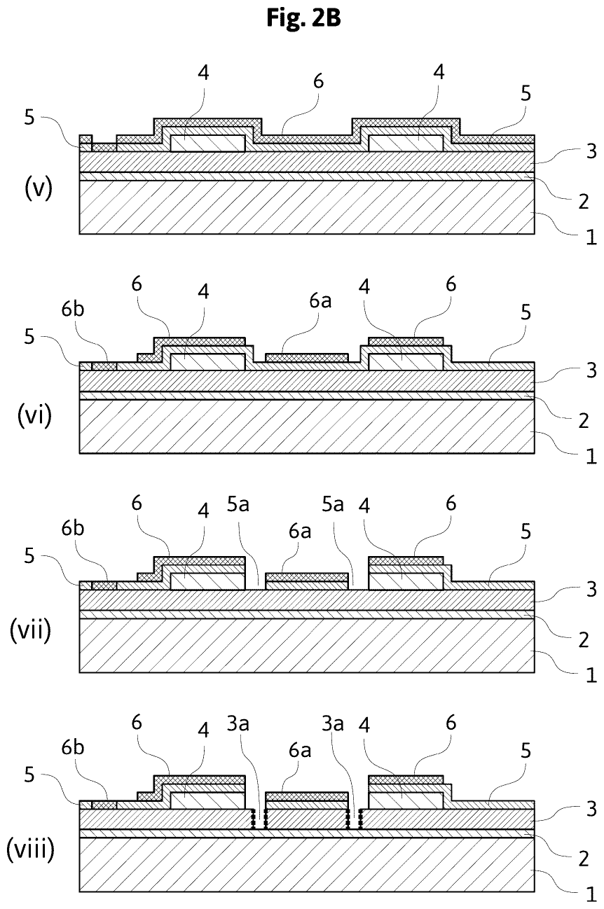

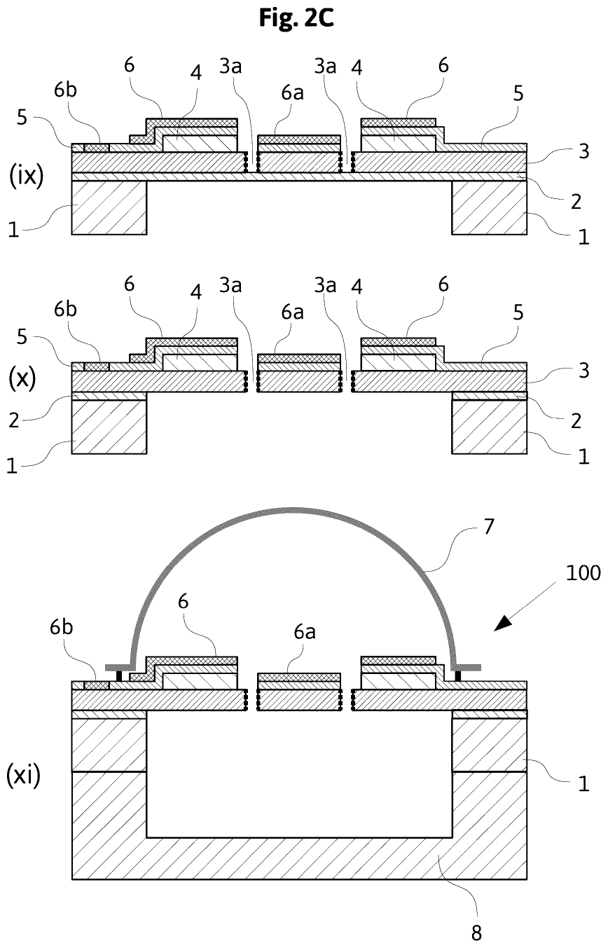

First, a background example is described below with reference to FIG. 1 and FIGS. 2A-2C, which is intended to facilitate understanding of the exemplary embodiments and advantages described below. However, the method on which FIG. 1 and FIGS. 2A-2C are based is not actually already publicly known prior art. A generic prior art method can be found, for example, in US 2009/0185253 A1.

Even if the following description with reference to FIG. 1 and FIGS. 2A-2C refers to a background example, any technical details and/or features of the method, the manufacturing sequence, the layer structure and in particular to individual steps and/or layers of the layer structure and/or to their possible materials that may be described may also relate to corresponding details and/or features of the embodiments described below, unless a difference is explicitly pointed out.

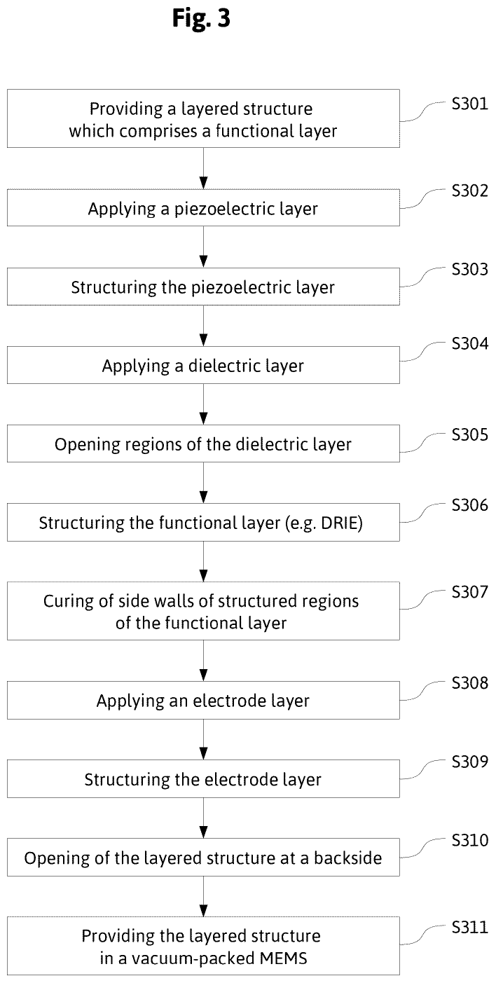

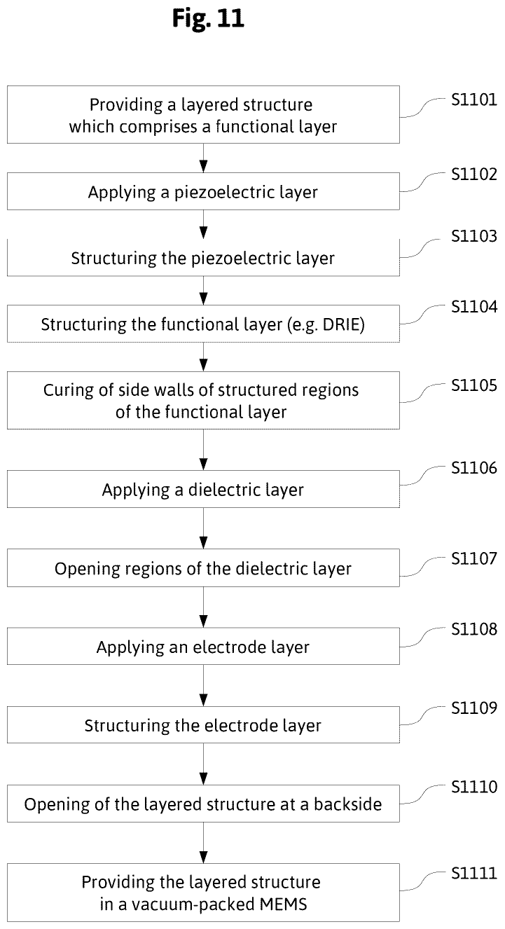

In particular, it should be noted that the steps S101 to S104 of FIG. 1 as well as the manufacturing sequence (i) to (iv) of FIG. 2A and the description thereof are always to be used for the exemplary embodiments of FIGS. 3 to 10, and the steps S101 to S103 of FIG. 1 as well as the manufacturing sequence (i) to (iii) of FIG. 2A and the description thereof are also to be used for the exemplary embodiments of FIGS. 11 to 13.

FIG. 1 shows an exemplary flowchart of a process for manufacturing a layered structure for a MEMS apparatus according to a background example, and FIGS. 2A-2C show exemplary sectional views of the layered structure during the manufacturing process according to an exemplary manufacturing sequence based on the process according to FIG. 1.

With reference to FIG. 1, in an exemplary step S101, a layer structure is provided which comprises a substrate layer 1 and a functional layer 3 (often referred to as a Device Layer). The layer structure shown in FIG. 2A (i) is also based on a corresponding exemplary layer structure. The layer structure according to FIG. 2A (i) exemplarily comprises an intermediate layer 2 (e.g. a passivation layer), which is exemplarily arranged between the substrate layer 1 and the functional layer 3, wherein the functional layer 3 is exemplarily formed on the intermediate layer 2.

In an exemplary step S102 of the method according to FIG. 1, a piezoelectric layer 4 is applied to the functional layer 3. According to steps S101 and S102, the layer structure according to FIG. 2A (i) thus comprises, by way of example, a piezoelectric layer 4 formed on the functional layer 3, the piezoelectric layer 4 being applied to the layer structure over the functional layer 3 in step S102 according to FIG. 1, by way of example.

In a further exemplary step S103 of the method according to FIG. 1, the piezoelectric layer 4, which is applied on or above the functional layer 3, is structured as an example; see also FIG. 2A (ii).

In a further exemplary step S104 of the method according to FIG. 1, a dielectric layer 5 is applied by way of example; see also FIG. 2A (iii). The dielectric layer 5 is applied to exemplary regions of the piezoelectric layer 4 according to FIG. 2A (iii) and is further applied to exemplary regions of the functional layer 3 which are opened after structuring of the piezoelectric layer 4.

In some exemplary embodiments, the applied dielectric layer 5 can be opened in selected regions. According to FIG. 2A (iv), for example, in region 5b the dielectric layer 5 is opened towards the functional layer 3, in particular before an electrode layer is applied (see further below), in order to provide a region 5b intended for a subsequent bond pad.

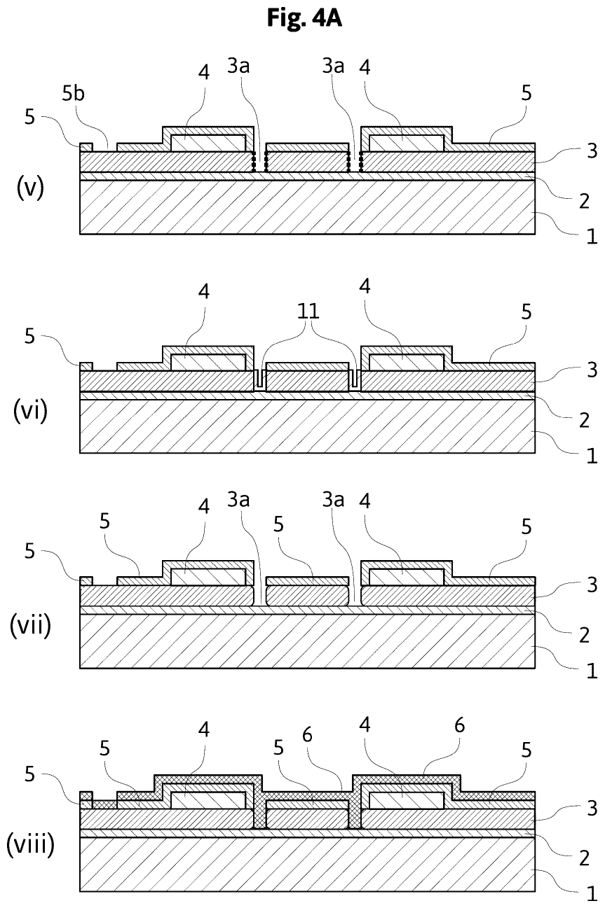

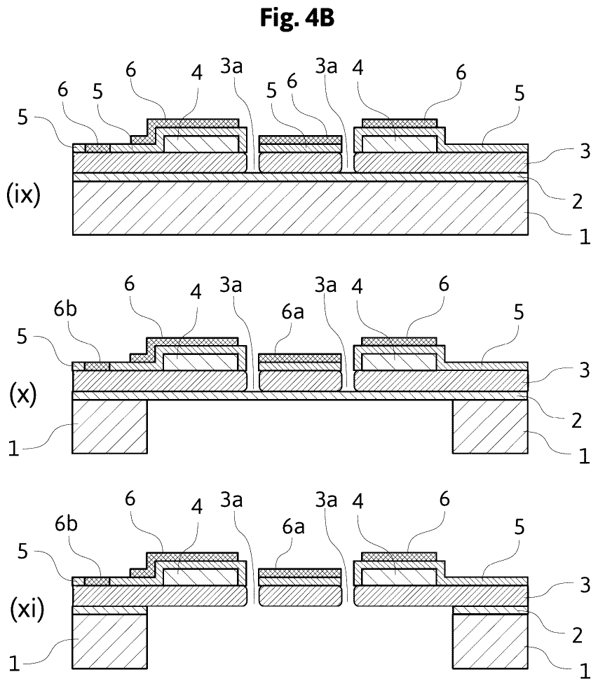

It should be noted that the above aspects and features of the background example also relate analogously to the initial manufacturing steps of the exemplary embodiments described later. In particular, all later described exemplary embodiments of the manufacturing sequences according to FIGS. 4A, 6A and 9A already start with an exemplary step (iv), which may be preceded by one or more of the steps (i) to (iv) according to FIG. 2A.

Referring again to FIG. 1, in a further exemplary step S105 of the method, an electrode layer 6 is applied to the dielectric layer 5, which may optionally have been previously opened in regions (e.g. opened region 5b for a subsequent bond pad); see also FIG. 2A (v). Here, when applying the electrode layer 6, the region 5b previously opened in the dielectric layer 5 is also filled with the material of the electrode layer 6, for example, to form a bond pad.

In a further exemplary step S106 of the method according to FIG. 1, the electrode layer 6, which is applied on or above the dielectric layer 5, is structured by way of example; see also FIG. 2A (vi). Here, for example, a bond pad 6b is formed with the material of the electrode layer 6 in the region 5b that was opened in the dielectric layer 5, which provides an electrical contact to the upper side of the functional layer 3 (and/or, in some exemplary embodiments, to a bottom electrode that can be electrically connected to the underside of the structured regions of the piezoelectric layer 4).

In the exemplary step S106 of structuring the electrode layer 6, the desired structure of the upper electrode (top electrode) for the upper electrical contacting of the piezoelectric layer 4 is formed. Furthermore, in the exemplary step S106 of structuring the electrode layer 6, a mirror 6a (e.g. a mirror layer with reflective surface) is formed in the center of the layer structure according to FIG. 2A (vi) by the material of the electrode layer 6.

In such examples, for example, the electrode layer may comprise metal, in particular aluminum, so that the surface of the electrode layer 6 already has a reflective surface and is suitable for forming the mirror 6a. In further examples, it is possible to provide a non-reflective or a non-metallic electrode layer (e.g. doped polycrystalline silicon), in which case a further, for example metallic mirror layer (e.g. as a thin-layer metal film, e.g. with a layer thickness of substantially greater than or equal to 100 nm and/or substantially less than or equal to 2000 nm) can be applied in the region of the layer 6a.

In a further exemplary step S107 of the method according to FIG. 1, the dielectric layer 5 is opened in regions 5a towards the functional layer 3, see also FIG. 2B (vii). In particular, these are regions 5a of the dielectric layer 5 to be opened, in which the underlying functional layer 3 is structured to form the mechanically effective structures of the MEMS apparatus.

In relation to a MEMS, “mechanically effective” here may mean in particular that the mechanically effective layer or the at least one mechanically effective functional layer (Device Layer) of the MEMS layered structure preferably forms the layer which, according to its structuring, is designed or formed to perform an oscillatory movement, in particular a one-dimensional or two-dimensional oscillatory movement, or in such a way that one or more structures or bodies formed in the mechanically effective layer or mechanically effective functional layer can perform an oscillation movement, in particular a one-dimensional or two-dimensional oscillation movement (e.g. about an oscillation/torsional axis or about two preferably transverse or in particular perpendicular oscillation/torsional axes, in particular e.g. for Lissajous scanning movements).

Preferably, the holding structure and/or spring structure for the movable structures or bodies of the mechanically effective layer or mechanically effective functional layer can also be formed in this mechanically effective layer or mechanically effective functional layer for this purpose. In some exemplary embodiments, the spring structure may comprise springs, in particular preferably bending springs and/or torsion springs, which are preferably designed to hold the mirror support element in such a way that the mirror support element can perform an oscillating rotational movement about the respective oscillation and/or torsion axis about the corresponding axis (e.g. torsional oscillations).

Furthermore, the formation of the mechanically effective layer or mechanically effective functional layer can preferably determine one or more of the resonant frequency or resonant frequencies of the MEMS, the deflection amplitudes and/or any dynamic deformations (e.g. in a holding structure and/or spring structure formed in the mechanically effective layer or mechanically effective functional layer).

In a further exemplary step S108 of the method according to FIG. 1, the functional layer 3 is structured in regions 3a, see also FIG. 2B (viii). In particular, the mechanically effective structures of the MEMS apparatus are formed in the functional layer. This includes, for example, the formation or exposure of a mirror support element (here, for example, the region of the functional layer 3 under the mirror layer 6a), which is formed, for example, from central regions of the functional layer 3, as well as any holding webs, which are formed from the functional layer 3, whereby the holding webs act, for example, as a spring structure and can hold the mirror support element so that it can oscillate about one, two or more oscillation or torsion axes.

In the methods commonly used in the prior art, so-called deep reactive ion etching (DRIE) is usually used for structuring the functional layer 3 in step S108 in order to form the deep trenches in the functional layer 3 (e.g. regions 3a in FIG. 2B (viii)). This is sometimes referred to as the Bosch process in the field of MEMS apparatus manufacturing, as it is based on a process developed by Bosch in the 1990s.

When using such dry etching processes for structuring the oscillating bodies and holding spring structure in the functional layer 3, damage or unevenness occurs on the etched side walls in the structured regions of the functional layer due to the process, in particular so-called scallops (i.e. surface corrugations, surface notches, etc. ; see e.g. the irregularities indicated by the black dots in the regions 3a in FIG. 2B (ix)) or e.g. also any sidewall breakthroughs and/or atomic defects. In addition, the mask used for structuring causes a direct transfer into the material of the functional layer 3 (usually silicon) and therefore the structures manufactured usually may have right-angled corners.

At the locations of surface damage (such as scallops, sidewall breakthroughs and atomic defects) on the sidewalls of the trenches of the structured functional layer 3 and at the formed right-angled corners, high stress can occur during the resonant oscillations, which can lead to premature fractures in structures of the functional layer 3. These disadvantages can be conveniently avoided in the exemplary embodiments described below. Compared to the state of the art, i.e. when components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be significantly reduced and, in particular, larger deflection angles or deflection amplitudes can also be made possible, even though fractures of the deflection structures or the spring structure would already occur in components manufactured according to the state of the art.

In a further exemplary step S109 of the method according to FIG. 1, the layer structure is exemplarily opened on the rear side in order to expose the functional layer 3 on the side opposite the piezoelectric layer 4; see also FIG. 2B (ix), in which the substrate layer 1 is exemplarily opened on the rear side towards the intermediate layer 2, and FIG. 2B (x), in which the intermediate layer 2 is exemplarily opened on the rear side towards the functional layer 3.

In a further exemplary step S110 of the method according to FIG. 1, the manufactured layer structure is provided in a vacuum-packed MEMS apparatus 100 according to FIG. 2B (xi). Here, by way of example, the layered structure was hermetically sealed from above with a translucent dome element 7 (e.g. a glass dome) and from below with a base body element 8 under a vacuum atmosphere.

Thus, a vacuum-packed MEMS mirror device 100 (e.g., a MEMS mirror scanner) comprising the fabricated layered structure can be provided with piezoelectrically deflectable or controllable mirror 6a, see, e.g., FIG. 2B (xi).

Various exemplary embodiments are described below. Any details or exemplary features from the above examples, in particular relating to individual process steps and materials, may also apply analogously to the exemplary embodiments below, unless differences are explicitly pointed out. Furthermore, descriptions of details or exemplary features from the following exemplary embodiment, in particular of individual process steps and materials, can also apply analogously to other exemplary embodiments, unless differences are explicitly pointed out.

In contrast to the above example, some exemplary embodiments preferably provide for a curing step, in particular for curing structured regions of the functional layer, preferably at temperatures substantially greater than or equal to 700° C.

In some preferred exemplary embodiments, the curing of structured regions of the functional layer can be carried out for at least partial smoothing of side walls of the trenches in the functional layer and/or for rounding of corners of the trenches in the functional layer. Smoothing the side walls of the trenches in the structured regions of the functional layer may mean in particular that the unevenness and/or surface effects or defects that occur on the side walls during the structuring of the functional layer as a result of the process are reduced, so that, relative to the state of the side wall surfaces after the structuring of the functional layer, smoother side wall surfaces are present after curing, up to a possibly completely smooth and/or crystal defect-free side wall. Preferably, the sidewall surfaces can have a roughness substantially less than or equal to 50 nm after curing, preferably in particular substantially less than or equal to 30 nm and particularly preferably in particular substantially less than or equal to 10 nm.

In some preferred exemplary embodiments, the curing of structured regions of the functional layer may preferably be carried out at temperatures substantially greater than or equal to 800° C. In some preferred exemplary embodiments, the curing of structured regions of the functional layer may be carried out at temperatures substantially less than or equal to 1400° C., in particular preferably at temperatures substantially less than or equal to 1350° C. Preferably, in some exemplary embodiments, the temperatures in the curing step or preferably in the entire manufacturing process should not exceed 1400° C., more preferably 1350° C., since the melting point of silicon is about 1410° C., as the substrate layer and/or the functional layer may typically comprise silicon.

FIG. 3 shows an exemplary flow diagram of a process for manufacturing a layered structure for a MEMS apparatus according to some exemplary embodiments of the present disclosure.

The first steps of the process according to FIG. 3 correspond, by way of example, to steps S101 to S104 of the process according to FIG. 1 or the exemplary manufacturing sequence (i) to (v) according to FIG. 2A. Following FIG. 2A (v), the subsequent FIGS. 4A-4B show exemplary sectional views of the layer structure during the manufacturing process according to an exemplary manufacturing sequence based on the process according to FIG. 3.

With reference to FIG. 3 and FIG. 2A (i) to (v), in an exemplary step S301 (e.g. analogous to S101 in FIG. 1), a layer structure comprising the substrate layer 1 and the functional layer 3 is provided. In exemplary step S302 (e.g. analogous to S102 in FIG. 1), the piezoelectric layer 4 is applied to the functional layer 3.

In some exemplary embodiments, the substrate layer 1 may, for example, be formed from silicon or comprise silicon. In some preferred exemplary embodiments, the substrate layer 1 can be provided, for example, as an SCS wafer (SCS, single crystal silicon), i.e., for example, as a crystalline bulk silicon substrate. Furthermore, the substrate layer can also be provided by an SOI wafer, which can already comprise the substrate layer 1 and, for example, also the functional layer 3 and/or the intermediate layer(s) 2. SOI wafers can comprise a handling wafer, which can consist, for example, of crystalline bulk silicon substrate, exemplarily followed by an intermediate layer (typically, for example, a silicon oxide with approx. 100-2000 nm), but can also consist of other preferably dielectric layers, such as silicon nitride, silicon oxynitride or aluminum oxide. In particular, different intermediate layers can consist of different materials.

In some exemplary embodiments, the intermediate layer 2 can thus be provided as silicon oxide, in particular silicon dioxide, or at least comprise silicon oxide, in particular silicon dioxide. The intermediate layer 2 can then be manufactured, for example, by wet and/or dry oxidation. In some exemplary embodiments, the intermediate layer 2 may also additionally or alternatively comprise silicon nitride (e.g. Si₃N₄), aluminum oxide (e.g. Al₂O₃) and/or silicon oxynitride (e.g. SiON).

The functional layer 3 (Device Layer) can, for example, be made of silicon or comprise silicon. In some exemplary embodiments, the functional layer 3 can have a layer thickness of substantially 5-300 μm. In some exemplary embodiment, the functional layer 3 can be present as a pure crystalline substrate, in particular preferably as a single crystal (e.g. SCS), or in some further exemplary embodiments it can be applied by epitaxial deposition processes, in particular in polycrystalline form (polycrystal).

In some exemplary embodiments, an electrode layer can be provided between the functional layer 3 and the piezoelectric layer 4, which electrode layer can form a bottom electrode, e.g. made of metal (e.g. molybdenum), which electrically contacts the piezoelectric layer from below.

In preferred exemplary embodiments, such an exemplary bottom electrode layer under the piezoelectric layer 4 can be designed to be stable at high temperatures, e.g. as doped polycrystalline silicon. In some further exemplary embodiments, the functional layer 3 may itself comprise doped polycrystalline silicon or be formed from doped polycrystalline silicon, at least in the regions of the subsequently structured piezoelectric layer 4. In some exemplary embodiments, the functional layer 3 can on the one hand form the mechanically effective elements (e.g. mirror support element and/or holding structure or spring structure) and also serve as a high-temperature-stable base electrode for the piezoelectric layer 4.

The piezoelectric layer 4 may preferably comprise piezoelectric material or be formed from piezoelectric material which preferably has high piezoelectric, pyroelectric and/or ferroelectric constants.

In some preferred exemplary embodiments, the piezoelectric layer 4 may comprise, for example, aluminum nitride (AlN), aluminum scandium nitride (AlScN), lead zirconate titanate (PZT) and/or niobium doped PZT (PZT-Nb). The piezoelectric layer 4 may also comprise semi-crystalline polymer materials such as PVDF (polyvinylidene fluoride (CF2-CH2)n).

In a further exemplary step S303 (e.g. analogous to S103 in FIG. 1), the piezoelectric layer 4, which is applied to or above the functional layer 3, is structured, in particular preferably by a wet and/or dry etching process.

In some exemplary embodiments, the remaining regions of the piezoelectric layer 4 define the piezoelectric elements and/or drive and/or sensing elements (e.g. actuator and/or sensor surfaces) in the later MEMS structure for generating, driving, controlling and/or sensing the movements or oscillations of the movably held components or elements of the MEMS.

In the further exemplary step S304 (e.g. analogous to S104 in FIG. 1), the dielectric layer 5 is applied by way of example. The dielectric layer 5 is applied to exemplary regions of the piezoelectric layer 4 and is further applied to exemplary regions of the functional layer 3 which are open after structuring of the piezoelectric layer 4.

The dielectric layer 5 may, for example, comprise silicon oxide, in particular SiO2, or be formed from silicon oxide, in particular SiO2. In further exemplary embodiments, the dielectric layer 5 may comprise or be formed from silicon nitride (e.g. Si₃N₄) and/or aluminum oxide (Al₂O₃), oxynitride and/or silicon oxynitride (e.g. SiON).

In some exemplary embodiments, the applied dielectric layer 5 may be opened in selected regions, for example by wet and/or dry etching, for example to provide a region 5b that may be provided for a subsequent bond pad. In some exemplary embodiments, the applied dielectric layer 5 may also be opened or partially opened over the structured regions of the piezoelectric layer 4.

Compared to the sequence of the background example according to FIG. 1, in the method according to FIG. 3, the application of the electrode layer is not yet carried out before the structuring of the functional layer 3, as an example, in order to preferably enable a curing step, which can follow after the structuring of the functional layer 3, at high temperatures above approx. 700° C. (i.e. at temperatures substantially greater than or equal to 700° C.) to possibly approx. 1250° C. (i.e. at temperatures substantially less than or equal to 1250° C.), which temperatures an electrode layer already applied in the usual way, e.g. made of aluminum (melting point at approx. 660° C.), could not withstand.

In a further exemplary step S305 of the method according to FIG. 3 (e.g. analogous to step S107 in FIG. 1), the dielectric layer 5 is opened towards the functional layer 3 in regions 5a. In particular, these are regions 5a of the dielectric layer 5 to be opened, in which the underlying functional layer 3 is structured to form the mechanically effective structures of the MEMS apparatus.

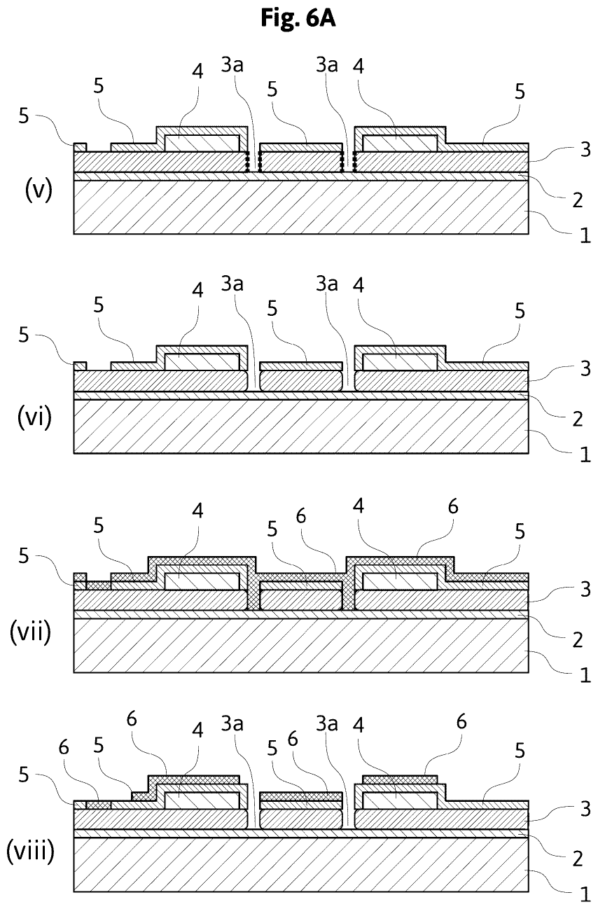

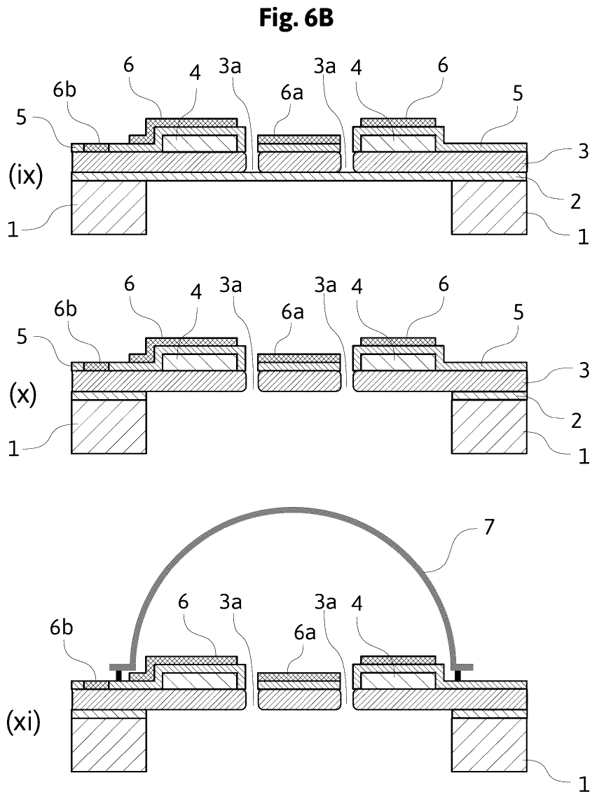

In some particularly preferred exemplary embodiments, it may be exemplarily provided here that the remaining regions of the piezoelectric layer 4 do further remain completely encapsulated by the dielectric layer 5 (see, for example, FIG. 4A (v) and also FIG. 6A (v)), i.e. the remaining regions of the piezoelectric layer 4 are or do remain completely encapsulated between the functional layer 3 and the dielectric layer 5, as an example.

Conveniently, the layer structure can nevertheless be subjected to high-temperature processes (e.g. at above about 700° C. to 1250° C.) without detrimentally affecting the encapsulated regions of the piezoelectric layer 4. It can be conveniently enabled, for example, in some exemplary embodiments with one or more curing steps at high temperatures greater than or equal to 700° C., such as the sacrificial oxidation processes described further below at, for example, about 800° C.-1250° C. (see, for example, the exemplary manufacture sequence according to FIGS. 4A-4B) and/or hydrogen annealing at, for example, about 1000° C.-1250° C. (see, for example, the exemplary manufacture sequence according to FIGS. 6A-6B).

It was recognized, for example, that this encapsulation of the structured regions of the piezoelectric layer 4, e.g. by the dielectric layer, conveniently protects the structured regions of the piezoelectric layer 4 despite the high temperatures in the curing step and despite the chemically aggressive media (e.g. oxygen or hydrogen), so that even piezoelectric materials that are not stable at high temperatures or not so chemically resistant, such as PZT, can still be used as a piezoelectric material (encapsulated in the curing step). In some exemplary embodiments where high-temperature-stable and/or chemically resistant piezoelectric materials are used, it is not necessary to encapsulate the structured regions of the piezoelectric layer 4.

In a further exemplary step S306 of the method according to FIG. 3 (e.g. analogous to step S108 in FIG. 1), the functional layer 3 is structured in regions 3a, see also FIG. 4A (v). In particular, the mechanically effective structures of the MEMS apparatus are formed in the functional layer 3, preferably by high-rate etching or deep reactive ion etching (DRIE for short).

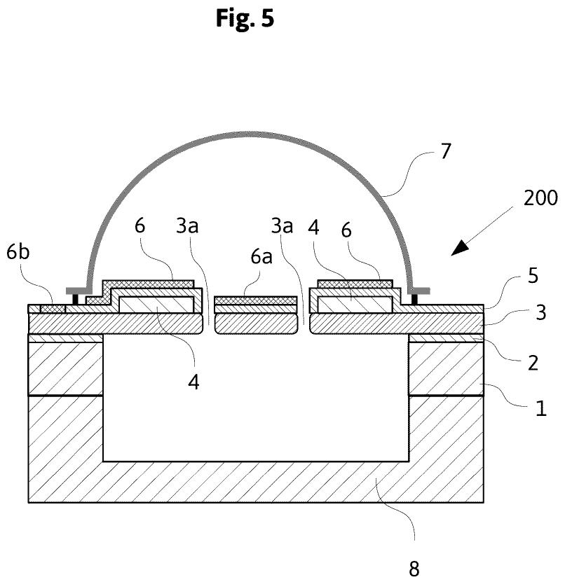

Structuring the functional layer 3 comprises, for example, forming or exposing the mirror support element formed from the functional layer 3 (under the subsequently applied mirror layer 6a, see e.g. FIG. 5) and the holding webs (spring structure), which are formed from the functional layer 3 and act as a holding spring structure, and which can hold the mirror support element so that it can oscillate about one, two or more oscillation and/or torsion axes. In some exemplary embodiments, the spring structure may comprise springs, in particular preferably bending and/or torsion springs, which are preferably designed to hold the mirror support element such that the mirror support element can perform an oscillating rotational movement about the respective oscillation and/or torsion axis about the corresponding axis (e.g. torsional oscillations).

In some exemplary embodiments, the reactive ion depth etching for structuring the functional layer 3 can be performed using a photolithography mask, for example.

The partial opening of the dielectric layer 5 can be carried out separately beforehand or in the same step using the same photolithography mask. For example, the photolithography mask can then be removed using a plasma or a wet-chemical process.

In general, all of the structuring steps of the present disclosure can be performed using photolithography masks that can be removed using a plasma or wet chemical process.

In another exemplary step S307 of the method according to FIG. 3, an exemplary curing step is performed at high temperatures substantially greater than or equal to 700° C. to smoothen sidewalls of the regions 3a of the functional layer 3 that was deep etched in step S306 and to round corners of the regions 3a of the functional layer 3.

In some exemplary embodiments, the curing step S307 may comprise a step of oxidizing the surface of the regions 3a of the functional layer 3 at oxidation temperatures (e.g., temperatures substantially greater than or equal to 700° C., in particular substantially greater than or equal to 800° C. or more, optionally preferably substantially less than or equal to 1250° C.); see, for example, the exemplary oxidation layer 11 shown in FIG. 4A (vi).

For example, in the manufacturing sequence according to FIGS. 4A and 4B, subsequent to the structuring S306 of the functional layer 3, a sacrificial oxidation is carried out as a curing step according to S307 (see e.g. FIG. 4A (vi)).

Through exemplary oxidation or sacrificial oxidation in the curing step S307, the surface effects or surface defects created during etching (e.g. unevenness, such as formed noses, waves, so-called scallops, etc., as well as other surface defects such as crystal defects, etchings, sidewall breakthroughs or atomic defects, etc.) on the sidewalls of the depth-etched sidewalls of the regions 3a of the functional layer 3 can be oxidized.

After sacrificial oxidation, the sacrificial oxidation layer 11 can preferably be selectively removed exemplarily in the curing step S307 and, exemplarily in the curing step S307, after selective removal of the sacrificial oxidation layer 11, smoothened sidewalls of the regions 3a of the functional layer 3 with reduced unevenness of the sidewalls and rounded corners do remain; see e.g. FIG. 4A (vii)

In particular, etching scallops as well as other surface defects (e.g. crystal defects, etching, sidewall breakthroughs and atomic defects, etc.) can be reduced or eliminated so that smoothened sidewalls are formed, possibly up to complete transformation into a completely smooth and/or crystal defect-free sidewalls. In addition, the right-angled structural corners that were created during the structuring of the functional layer can be rounded off (round or rounded structural corners).

The corresponding layer structure or the MEMS apparatus comprising the layer structure has, after the corresponding curing step S307, smoothened side walls with reduced unevenness or even smooth and/or crystal defect-free (e.g. completely smoothened) sidewalls and rounded corners on the structured regions and trenches of the functional layer, so that fracture limits of the moving or oscillating parts of the functional layer or in particular spring structure formed in the functional layer can be significantly increased and the occurrence of premature fractures of the spring structure can be successfully reduced. Compared to the state of the art, i.e. when components are manufactured without cured side walls (i.e. in particular without smoothened side walls and/or without rounded corners), in which fractures can occur in particular already at smaller deflection angles or deflection amplitudes, the occurrence of fractures of the deflection structures or the spring structure can be conveniently significantly reduced and, in particular, larger deflection angles or deflection amplitudes can also be made possible, at which larger deflection angles or deflection amplitudes fractures of the deflection structures or the spring structure would already occur in components manufactured according to the state of the art.

In a further exemplary step S308 of the method according to FIG. 3, the electrode layer 6 is applied after the curing step S307; see also FIG. 4A (viii). Here, for example, the region 5b, which was previously opened in the dielectric layer 5, is also filled with the material of the electrode layer, in particular to form a bond pad.

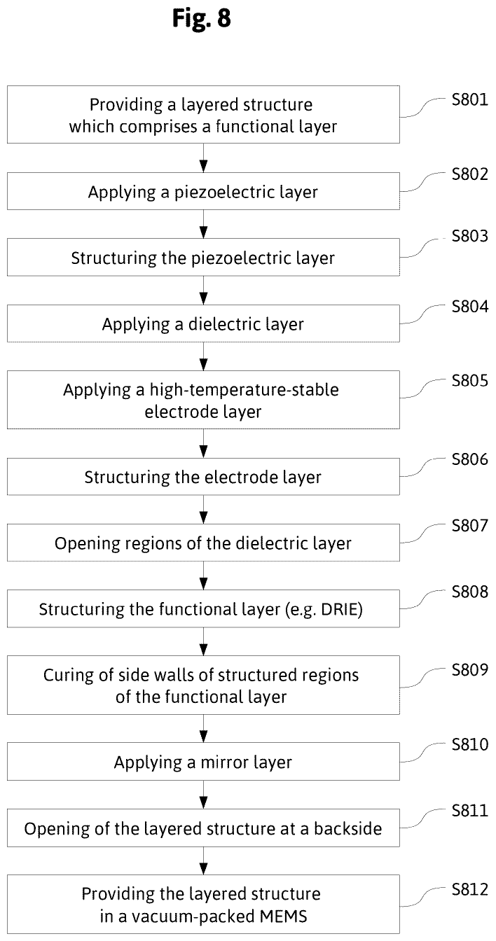

In some preferred exemplary embodiments, a top electrode layer 6 can be deposited over the entire surface, e.g. made of metal, in particular, for example, aluminum. In further exemplary embodiments, high-temperature-stable materials, in particular e.g. high-temperature-stable metals, can also be used for the electrode layer. In some exemplary embodiments, the curing step can also take place after the electrode layer has been applied and/or structured and optionally after the layer structure, which preferably comprises high-temperature-stable and chemically resistant materials, has been opened on the backside; see, for example, the exemplary embodiments described below in accordance with FIGS. 8 to 10.

In a further exemplary step S309 of the method according to FIG. 3, the electrode layer 6, which is applied on or above the dielectric layer 5, is structured by way of example; see also FIG. 4B (ix). Here, furthermore, a bond pad 6b can be formed, by way of example, in the region 5b in which the dielectric layer 5 has been opened, with the material of the electrode layer 6, which provides an electrical contact to the upper side of the functional layer 3 (and/or, in exemplary embodiments, to a bottom electrode, which can be electrically connected to the underside of the structured regions of the piezoelectric layer 4).

In the exemplary step S309 of structuring the electrode layer 6, the desired structure of the upper electrode (top electrode) for the upper electrical contacting of the piezoelectric layer 4 is formed. Furthermore, in the exemplary step S309 of structuring the electrode layer 6, a mirror 6a (mirror layer with reflective surface) is formed in the center of the layer structure according to FIG. 4B (iv) by the material of the electrode layer 6.

In some exemplary embodiments, for example, the electrode layer may comprise metal, in particular aluminum, so that the surface of the electrode layer 6 already has a reflective surface and is suitable for forming the mirror 6a. In some preferred exemplary embodiments, a top electrode layer deposited over the entire surface, e.g. of metal, in particular aluminum for example, can be structured via photolithographic steps using wet and or dry chemistry, e.g. by spray-coat lithography or alternatively via a lift-off process in which the lithography takes place before the metal deposition. In some exemplary embodiments, the electrode layer can also be applied by shadow mask deposition.

In some exemplary embodiments, it is possible to provide a non-reflective or a non-metallic electrode layer (e.g. doped polycrystalline silicon), in which case a further, for example metallic mirror layer (e.g. as a thin-layer metal film, e.g. with a layer thickness of substantially greater than or equal to 100 nm and/or substantially less than or equal to 2000 nm) can be applied in the region of the layer 6a. In some preferred exemplary embodiments, the material of the metallic mirror layer can be selected depending on the desired application for the respective wavelength range, in particular with very good reflection behavior in the wavelength range of the desired application, for example aluminum or silver for visible light (e.g. substantially at wavelengths of 400-700 nm) or gold for infrared light or infrared radiation (e.g. substantially at wavelengths of 850-2000 nm).

In a further exemplary step S310 of the process according to FIG. 3 (e.g. analogous to S109 in FIG. 1), the layer structure is exemplarily opened at the back in order to expose the functional layer 3 on the side opposite the piezoelectric layer 4; see also FIG. 4B (x), in which, for example, the substrate layer 1 is opened at the back towards the intermediate layer 2 (e.g. by high rate etching or reactive ion depth etching), and FIG. 4B (xi), in which, for example, the intermediate layer 2 is opened at the back towards the functional layer 3.

In a further exemplary step S311 of the method according to FIG. 3 (e.g. analogous to S110 in FIG. 1), the manufactured layer structure is provided in a vacuum-packed MEMS apparatus 200 according to FIG. 5. Here, for example, the layered structure was hermetically sealed from above with a translucent cover element 7 (e.g. a translucent dome element or a glass dome) and from below with a base body element 8 under a vacuum atmosphere (e.g. vacuum encapsulation). In some exemplary embodiments, differently shaped cover elements or 3D-shaped cover elements are also possible (e.g. angular or planar). The material of the cover elements is preferably translucent, e.g. glass or other optically transparent materials (e.g. approx. 400-2500 nm), such as borosilicate glass (e.g. Borofloat® BF33 by SCHOTT).

FIG. 5 shows an exemplary sectional view of a MEMS apparatus 200 manufactured according to the exemplary manufacturing sequence of FIGS. 4A-4B. Consequently, a vacuum-packed MEMS mirror device 200 (e.g., a MEMS mirror scanner) comprising the manufactured layered structure can be provided with piezoelectrically deflectable or controllable mirrors 6a, wherein the corresponding layered structure or the MEMS apparatus 200 comprising the layered structure conveniently has smoothened or smooth and/or crystal defect-free sidewalls and rounded corners at the structured regions and trenches of the functional layer, so that fracture limits of the moving or oscillating parts of the functional layer or, in particular, of the spring structure formed in the functional layer can be significantly increased and the occurrence of premature fractures of the spring structure can be successfully reduced. Compared to the state of the art, i.e. when components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be conveniently significantly reduced and, in particular, larger deflection angles or deflection amplitudes can also be made possible, at which larger deflection angles or deflection amplitudes fractures of the deflection structures or the spring structure would already occur in components manufactured according to the state of the art.

FIGS. 6A-6B show exemplary sectional views of the layer structure during the manufacturing process according to a further exemplary manufacturing sequence based on the process according to FIG. 3. Consequently, the exemplary sequence according to FIGS. 6A-6B is a further exemplary embodiment of the process according to FIG. 3.

The first steps of the method according to FIG. 3 again correspond, by way of example, to steps S101 to S104 of the method according to FIG. 1 or the exemplary manufacturing sequence (i) to (v) according to FIG. 2A. Following FIG. 2A (v), FIGS. 6A-6B illustrate the exemplary manufacturing sequence based on some further exemplary embodiments of the method according to FIG. 3.

Here too, in contrast to the sequence of the background example according to FIG. 1, in the method according to FIG. 3 in conjunction with FIGS. 6A-6B, the application of the electrode layer is not yet carried out, for example, before the structuring of the functional layer 3, in order to preferably enable an curing step following the structuring of the functional layer 3 at high temperatures substantially greater than or equal to 700° C., which an electrode layer, e.g. made of aluminum, which has already been applied in the usual manner could not withstand.

In exemplary step S306 of the method according to FIG. 3 (e.g. analogous to step S108 in FIG. 1), the functional layer 3 is also structured in exemplary regions 3a in the manufacturing sequence according to FIGS. 6A-6B, see FIG. 6A (v).

In particular, the mechanically effective structures of the MEMS apparatus are again formed in the functional layer, preferably by high-rate etching or deep reactive ion etching (DRIE for short). Structuring the functional layer 3 comprises, for example, forming or exposing the mirror support element under the mirror layer 6a, whereby the mirror support element is formed out of the functional layer 3, as well as the holding webs (spring structure), which can be formed out of the functional layer 3 and can act as a spring system, and which can hold the mirror support element so that it can oscillate about one, two or more oscillation and/or torsion axes. In some exemplary embodiments, the spring structure may comprise springs, in particular preferably bending and/or torsion springs, which are preferably designed to hold the mirror support element in such a way that the mirror support element can perform an oscillating rotational movement about the respective oscillation and/or torsion axis (e.g. torsional oscillations).

Furthermore, all descriptions of steps S301 to S306 from above are also applicable to the manufacturing sequence according to FIGS. 6A-6B.

In the further exemplary step S307 of the method according to FIG. 3, also in the manufacturing sequence according to FIGS. 6A-6B, an curing step is exemplarily carried out at high temperatures of substantially greater than or equal to 700° C. in order to smooth the side walls of the regions 3a of the functional layer 3, which are depth-etched in step S306, and to round off corners of the regions 3a of the functional layer 3.

In some exemplary embodiments, the curing step S307 may comprise a step of subjecting the surface of the regions 3a of the functional layer 3 to a hydrogen annealing step at temperatures substantially greater than or equal to 1000° C. and preferably substantially less than or equal to 1250° C. (alternatively or also in addition to the sacrificial oxidation described above).

As an example, in the manufacturing sequence according to FIGS. 6A and 6B, following the structuring S306 of the functional layer 3 as a curing step according to S307, the surface of the regions 3a of the functional layer 3 is subjected to a hydrogen annealing step at temperatures substantially greater than or equal to 900° C., in particular substantially greater than or equal to 1000° C., and preferably substantially less than or equal to 1350° C., in particular substantially less than or equal to 1250° C. (see e.g. FIG. 6A (vi)). hydrogen annealing (see e.g. FIG. 6A (vi)).

After hydrogen annealing in some exemplary embodiments of the curing step S307, conveniently smoothened side walls of the regions 3a of the functional layer 3 with rounded corners remain; see, for example, FIG. 6A (vi).

The hydrogen annealing or curing step results in smoothened or smooth side walls and rounded corners on the surface of the regions 3a of the functional layer 3. In particular, any etching scallops as well as any other surface defects (e.g. crystal defects, etching, sidewall breakthroughs and atomic defects, etc.) can be reduced or eliminated, so that smoothened sidewalls are formed, up to complete transformation into a completely smooth and/or crystal defect-free sidewall. In addition, the right-angled structural corners that were created during the structuring of the functional layer can be rounded off (round or rounded structural corners).

After the corresponding curing step S307, the corresponding layer structure or the MEMS apparatus comprising the layer structure conveniently has smoothened or is smooth and/or crystal defect-free sidewalls and rounded corners at the structured regions and trenches of the functional layer, so that fracture limits of the moving or oscillating parts of the functional layer or in particular of the spring structure formed in the functional layer can be significantly increased and the occurrence of early fractures of the spring structure can be successfully reduced. Compared to the state of the art, i.e. when components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be conveniently significantly reduced and, in particular, larger deflection angles or deflection amplitudes can also be made possible, at which larger deflection angles or deflection amplitudes fractures of the deflection structures or the spring structure would already occur in components manufactured according to the state of the art.

In the exemplary step S308 of the method according to FIG. 3, the electrode layer 6 is applied after the curing step S307; see also FIG. 6A (vii). Here, for example, the region 5b previously opened in the dielectric layer 5 is also filled with the material of the electrode layer, in particular, for example, to form a bond pad.

In some preferred exemplary embodiments, an electrode layer 6 (top electrode layer) can be deposited over the entire surface, e.g. made of metal, in particular aluminum, for example. In some exemplary embodiments, high-temperature-stable materials, in particular e.g. high-temperature-stable metals, can also be used for the electrode layer. In some exemplary embodiments, the curing step can also take place after the electrode layer has been applied and/or structured and optionally also after the layer structure, which preferably comprises high-temperature-stable and chemically resistant materials, has been opened on the back; see, for example, the exemplary embodiments described below according to FIGS. 8 to 10.

In a further exemplary step S309 of the method according to FIG. 3, the electrode layer 6, which is applied to or over the dielectric layer 5, is structured; see also FIG. 6B (viii). Here, for example, a bond pad 6b is formed with the material of the electrode layer in the region 5b that is open in the dielectric layer 5, which can provide an electrical contact to the upper side of the functional layer 3.

In the further exemplary step S310 of the method according to FIG. 3 (e.g. analogous to S109 in FIG. 1), the layer structure is exemplarily opened on the rear side in order to expose the functional layer 3 on the side opposite the piezoelectric layer 4; see also FIG. 6B (ix), in which the substrate layer 1 is exemplarily opened on the rear side towards the intermediate layer 2, and FIG. 6B (x), in which the intermediate layer 2 is exemplarily opened on the rear side towards the functional layer 3.

In a further exemplary step S311 of the method according to FIG. 3 (e.g. analogous to S110 in FIG. 1), the manufactured layer structure is exemplarily provided in a vacuum-packed MEMS apparatus 300 according to FIG. 6. Here, by way of example, the layered structure was hermetically sealed from above with a translucent cover element 7 (e.g. a translucent dome element or a glass dome) (see e.g. FIG. 6B (xi)) and hermetically sealed from below with a base body element 8 under a vacuum atmosphere (e.g. vacuum encapsulation). In some further exemplary embodiments, differently shaped cover elements or 3D-shaped cover elements are also possible (e.g. angular or planar). The material of the cover elements is preferably translucent, e.g. glass or other optically transparent materials (e.g. approx. 400-2500 nm), such as borosilicate glass (e.g. Borofloat® BF33 from SCHOTT).

Furthermore, all descriptions of steps S308 to S311 from above are also applicable to the manufacturing sequence according to FIGS. 6A-6B.

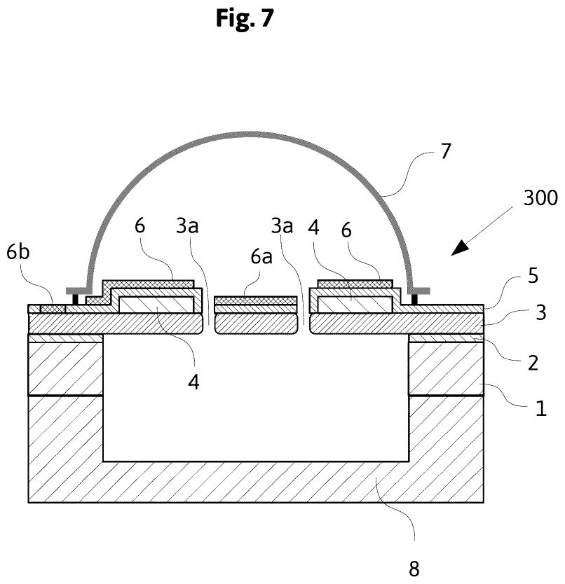

FIG. 7 shows an exemplary sectional view of a MEMS apparatus 300 that may be fabricated according to the exemplary fabrication sequence of FIGS. 6A-6B. Consequently, a vacuum-packed MEMS mirror device 300 (e.g., a MEMS mirror scanner) comprising the fabricated layered structure may be provided with piezoelectrically deflectable or steerable mirrors 6a, wherein the corresponding layered structure or MEMS apparatus 300 comprising the layered structure conveniently provides smoothened and/or smooth and/or crystal defect-free side walls and rounded corners at the structured regions and trenches of the functional layer, so that fracture limits of the moving or oscillating parts of the functional layer or, in particular, of the spring structure formed in the functional layer can be significantly increased and the occurrence of premature fractures of the spring structure can be successfully reduced. In comparison with the prior art, i.e. if components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be significantly reduced and, in particular, larger deflection angles or deflection amplitudes can also be made possible, at which larger deflection angles or deflection amplitudes fractures of the deflection structures or the spring structure would already occur in components manufactured according to the state of the art.

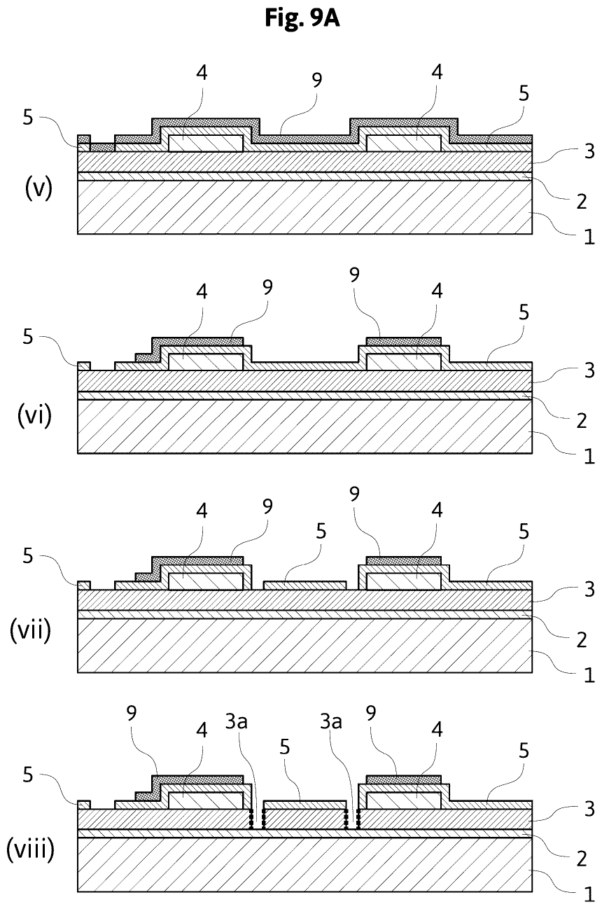

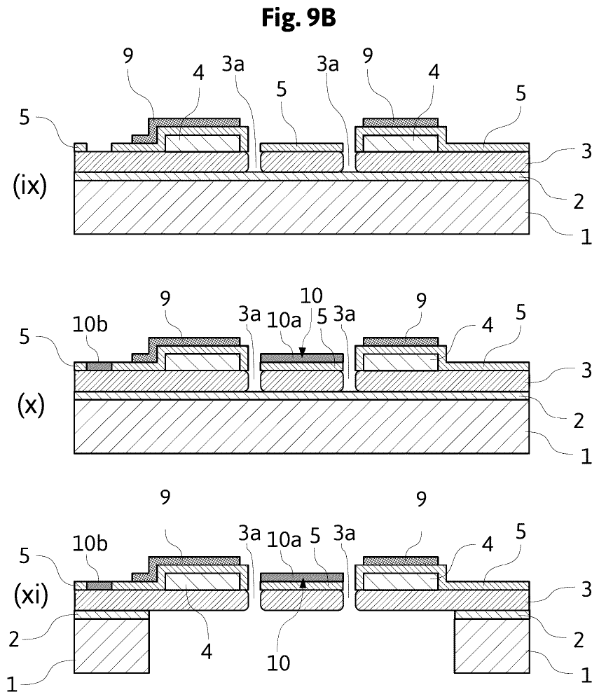

FIG. 8 shows an exemplary flowchart of a process for manufacturing a layered structure for a MEMS apparatus according to some further exemplary embodiments of the present disclosure. FIGS. 9A-9B show exemplary sectional views of the layered structure during the manufacturing process according to an exemplary manufacturing sequence based on the process according to FIG. 8.

However, the first steps of the process according to FIG. 8 initially correspond again, by way of example, to steps S101 to S104 of the process according to FIG. 1 or the exemplary manufacturing sequence (i) to (v) according to FIG. 2A. Following FIG. 2A (v), the subsequent FIGS. 9A-9B show exemplary sectional views of the layer structure during the manufacturing process according to an exemplary manufacturing sequence based on the process according to FIG. 8.

With reference to FIG. 8 and FIG. 2A (i) to (v), a layer structure is provided in an exemplary step S801 (e.g. analogous to S101 in FIG. 1), which exemplarily already comprises the substrate layer 1 and the functional layer 3. In exemplary step S802 (e.g. analogous to S102 in FIG. 1), the piezoelectric layer 4 is applied to the functional layer 3. In the further exemplary step S803 (e.g. analogous to S103 in FIG. 1), the piezoelectric layer 4, which is applied on or above the functional layer 3, is structured as an example.

In the further exemplary step S804 (e.g. analogous to S104 in FIG. 1), the dielectric layer 5 is applied by way of example. The dielectric layer 5 is applied to exemplary regions of the piezoelectric layer 4 and is further applied to exemplary regions of the functional layer 3 that are open after structuring of the piezoelectric layer 4. In some exemplary embodiments, the applied dielectric layer 5 can be opened in selected regions, for example to provide a region 5b intended for a subsequent bond pad. In some exemplary embodiments, the applied dielectric layer 5 may also be opened or partially opened over the structured regions of the piezoelectric layer

Furthermore, all descriptions of steps S301 to S304 from above are also applicable, by way of example, to the manufacturing sequence according to FIGS. 9A-9B in connection with steps S801 to S804 according to FIG. 8.

In a further exemplary step S805 of the method according to FIG. 1, an electrode layer 9 is applied to the dielectric layer 5, which can optionally be opened in regions beforehand; see also FIG. 9A (v).

In contrast to the sequence of the background example according to FIG. 1, a high-temperature-stable, electrically conductive material is used in step S805 when applying the electrode layer 9. In some preferred exemplary embodiments (instead of e.g. aluminum of the electrode layer 6 in FIGS. 2A-2C), a high-temperature-stable material can be used that can withstand temperatures substantially greater than or equal to 700° C., in some further exemplary embodiments preferably substantially greater than or equal to 800° C. and preferably greater than or equal to 1000° C., and in some further exemplary embodiments particularly preferably substantially greater than or equal to 1250° C.

In some particularly preferred exemplary embodiments, for example, a conductive silicon layer can be used as the high-temperature-stable material of the high-temperature-stable electrode layer 9 (e.g. deposited by physical vapor deposition, PVD, by chemical vapor deposition, CVD, or by plasma-enhanced chemical vapor deposition, PECVD, etc.). The use of a doped polysilicon as the (non-metallic) high-temperature-stable material of the high-temperature-stable electrode layer 9 is particularly preferred.

In some further preferred exemplary embodiments, alternatively or additionally, for example, a high-temperature-stable metal can be used as the material of the high-temperature-stable electrode layer 9 (e.g. molybdenum, platinum, tungsten, tungsten titanium or WTi, tungsten carbide or WC, etc.).

Such high-temperature-stable materials for use as the material of the high-temperature-stable electrode layer 9 enable the layer structure to be further compatible with a high-temperature-stable process sequence at temperatures substantially greater than or equal to 700° C. or substantially greater than or equal to 800° C., wherein in particular the already applied electrode layer 9 can also withstand a later curing step (e.g. sacrificial oxidation and/or hydrogen annealing according to the above exemplary embodiments) at temperatures substantially greater than or equal to 700° C., in particular between substantially 700° C. and 1250° C.

In a further exemplary step S806 of the method according to FIG. 8 (e.g. analogous to S106 in FIG. 1), the electrode layer 9, which is applied on or above the dielectric layer 5, is structured as an example; see also FIG. 9A (vi). In the exemplary step S806 of structuring the electrode layer 9, the desired structure of the overlying electrode (top electrode) for controlling the piezoelectric layer 4 can be formed.

In a further exemplary step S807 of the method according to FIG. 8 (e.g. analogous to S107 in FIG. 1), the dielectric layer 5 is exemplarily opened in regions 5a towards the functional layer 3, see also FIG. 9A (vii). In particular, these are regions 5a of the dielectric layer 5 to be opened, in which the underlying functional layer 3 is structured to form the mechanically effective structures (e.g. the spring structure) of the MEMS apparatus.

Again, in some exemplary embodiments, it is provided that the remaining regions of the piezoelectric layer 4 do remain completely encapsulated by the dielectric layer 5 (see e.g. FIG. 9A (vii)), i.e. the remaining regions of the piezoelectric layer 4 are or do remain completely encapsulated between the functional layer 3 and the dielectric layer 5, in particular preferably by way of example. Conveniently, the layer structure can still be subjected to high-temperature processes at temperatures substantially greater than or equal to 700° C., e.g. above approx. 700° C. to 1250° C., without impairing the encapsulated regions of the piezoelectric layer 4. This enables, for example, further curing steps such as the processes of sacrificial oxidation (at e.g. about 800° C.-1250° C.) and/or hydrogen annealing (at e.g. about 1000° C.-1250° C.) described further below, even if less high-temperature-stable and/or less chemically resistant materials are used under the encapsulation (e.g. for any bottom electrode and/or for the piezoelectric layer).

This encapsulation of the structured regions of the piezoelectric layer 4, e.g. by the dielectric layer, makes it possible to protect the structured regions of the piezoelectric layer 4 despite the high temperatures in the curing step and despite the chemically aggressive media (e.g. oxygen or hydrogen). This may mean that even piezoelectric materials that are not stable at high temperatures or not so chemically resistant, such as PZT, can still be used as a piezoelectric material (encapsulated in the curing step). In some exemplary embodiments with the use of high-temperature-stable and/or chemically resistant piezoelectric materials, it is not necessary to encapsulate the structured regions of the piezoelectric layer 4.

In addition or as an alternative to encapsulating the piezoelectric layer 4, for example by the dielectric layer or with encapsulating regions of the dielectric layer, the high-temperature-stable electrode layer 9 can also be used to encapsulate the structured regions of the piezoelectric layer 4. For this purpose, it may be provided in some exemplary embodiments that the remaining regions of the piezoelectric layer 4 are or do remain completely encapsulated by the high-temperature-stable electrode layer 9, i.e. the remaining regions of the piezoelectric layer 4 are or do remain completely encapsulated between the functional layer 3 and the high-temperature-stable electrode layer 9 (optionally with an interposed or partially interposed dielectric layer 5).

Conveniently, the layer structure can nevertheless be subjected to high-temperature processes at substantially greater than or equal to 700° C., e.g. at over approx. 700° C. to 1250° C., whereby in particular any less chemically resistant piezoelectric materials can be protected by the encapsulation of aggressive media, such as oxygen (e.g. in an curing step with sacrificial oxidation) and/or hydrogen (e.g. in an curing step involving hydrogen annealing).

This enables, for example, further curing steps such as the processes of sacrificial oxidation (at e.g. approx. 800° C.-1250° C.) and/or hydrogen annealing (at e.g. approx. 1000° C.-1250° C.) described below, even if less high-temperature-stable and/or less chemically resistant materials are used under the encapsulation (e.g. for any bottom electrode and/or for the piezoelectric layer).

In a further exemplary step S808 of the method according to FIG. 8 (e.g. analogous to S108 in FIG. 1), the functional layer 3 is structured in regions 3a, see also FIG. 9A (viii).

In particular, the mechanically effective structures of the MEMS apparatus are again formed in the functional layer, preferably by high-rate etching or deep reactive ion etching (DRIE for short). Structuring the functional layer 3 comprises, for example, forming or exposing the mirror support element, which is formed from the functional layer 3, as well as the holding webs (spring structure), which are formed from the functional layer 3 and act as a spring system, and which can hold the mirror support element so that it can oscillate about one, two or more oscillation and/or torsion axes. In some exemplary embodiments, the spring structure may comprise springs, in particular preferably bending and/or torsion springs, which are preferably designed to hold the mirror support element in such a way that the mirror support element can perform an oscillating rotational movement about the respective oscillating and/or torsional axis (e.g. torsional oscillations).

In the further exemplary step S809 of the method according to FIG. 8 (e.g. analogous to S307 in FIG. 3), also in the manufacturing sequence according to FIGS. 6A-6B, an exemplary curing step is carried out at high temperatures substantially greater than or equal to 700° C., in particular to smooth the side walls of the regions 3a of the functional layer 3 that are depth-etched in step S808 and to round off corners of the regions 3a of the functional layer 3.

In some exemplary embodiments, the curing step S809 may comprise a step of oxidizing the surface of the regions 3a of the functional layer 3 at temperatures substantially greater than or equal to 700° C., preferably at temperatures substantially greater than or equal to 800° C. (e.g., at about 800° C.-1250° C.). By way of example, after structuring S808 of the functional layer 3, sacrificial oxidation can be carried out as a curing step according to S809.

This oxidation can oxidize the surface effects created during etching (e.g. unevenness, such as formed noses, waves, so-called scallops, as well as any other surface defects, such as crystal defects, etching, sidewall breakthroughs and atomic defects, etc.) on the sidewalls of the depth-etched sidewalls of the regions 3a of the functional layer 3.

After sacrificial oxidation, the sacrificial oxidation layer 11 can preferably be selectively removed and, in particular, any etch scallops as well as any surface defects (e.g. crystal defects, etching, sidewall breakthroughs and atomic defects, etc.) can be reduced or eliminated, so that smoothened sidewalls are formed, up to complete transformation into a completely smooth and/or crystal defect-free sidewall.

In addition, the right-angled structural corners formed during the structuring of the functional layer can be rounded (round or rounded structural corners). In some exemplary embodiments of the curing step S809, conveniently smoothened side walls and rounded structural corners of the side walls of the regions 3a of the functional layer 3 remain after selective removal of the sacrificial oxidation layer 11; see, for example, FIG. 9B (ix)

In some exemplary embodiments, the curing step S809 may again comprise (alternatively or in addition to the surface oxidation) a step in which the surface of the regions 3a of the functional layer 3 is subjected to a hydrogen annealing step, e.g. at temperatures substantially greater than or equal to 1000° C., e.g. from about 1000° C. to 1250° C. Thus, for example, after structuring S808 of the functional layer 3 as a curing step according to S809, the surface of the regions 3a of the functional layer 3 can be subjected to a hydrogen annealing step at temperatures substantially greater than or equal to 1000° C., e.g. from about 1000° C. to 1250° C.

The hydrogen annealing or curing step results in smooth side walls and rounded corners on the surface of the regions 3a of the functional layer 3. In particular, any etching scallops as well as any surface defects (e.g. crystal defects, etchings, sidewall breakthroughs and atomic defects, etc.) can be reduced or eliminated, so that smoothened sidewalls are formed, up to the complete transformation into a completely smooth and/or crystal defect-free sidewall; see e.g. FIG. 9B (ix).

In some exemplary embodiments of the curing step S809, the surface effects or surface defects (e.g. formed noses, waves, so-called scallops, etc.) on the side walls of the depth-etched side walls of the regions 3a of the functional layer 3 can be smoothened by curing, e.g. by oxidation or sacrificial oxidation and/or by hydrogen annealing (analogous to S307 according to FIG. 3).

In particular, any etching scallops as well as any other surface defects (e.g. crystal defects, etchings, sidewall breakthroughs and atomic defects, etc.) can be reduced or eliminated so that smoothened sidewalls are formed, right up to complete transformation into a completely smooth and/or crystal defect-free sidewall. In addition, the right-angled structural corners created during the structuring of the functional layer can be rounded off (round or rounded structural corners). Consequently, after the curing step S809, conveniently smoothened side walls of the regions 3a of the functional layer 3 with rounded corners remain; see, for example, FIG. 9A (ix)

After the corresponding curing step S809, the corresponding layer structure or the MEMS apparatus comprising the layer structure conveniently has smoothened or smooth and/or crystal defect-free sidewalls and rounded corners at the structured regions and trenches of the functional layer, so that fracture limits of the moving or oscillating parts of the functional layer or in particular of the spring structure formed in the functional layer can be significantly increased and the occurrence of early fractures of the spring structure can be successfully reduced. Compared to the prior art, i.e. when components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be significantly reduced and, in particular, larger deflection angles or deflection amplitudes can also be made possible, at which larger deflection angles or deflection amplitudes fractures of the deflection structures or the spring structure would already occur in components manufactured according to the state of the art.

Furthermore, it may be expedient, in particular if an electrically conductive silicon-based electrode layer 9 has been applied in step S806, that a mirror layer is formed on the mirror support element of the functional layer 3, which is formed in step S806, following the curing step S809.

In some exemplary embodiments, the method according to FIG. 8 can therefore comprise, by way of example, a further step S810 of applying a mirror layer 10 to form the mirror 10a on the mirror support element of the functional layer 3; see also, for example, FIG. 9B (x).

Here again, a simple metal, such as aluminum, can also be used. In some preferred exemplary embodiments, the material of the metallic mirror layer can be selected depending on the desired application for the respective wavelength range, in particular with very good reflection behavior in the wavelength range of the desired application, for example aluminum or silver for visible light (e.g. substantially at wavelengths of 400-700 nm) or gold for infrared light or infrared radiation (e.g. substantially at wavelengths of 850-2000 nm). If a conductive material is used, this can also be used as an example to form the bond pad 10b; see also FIG. 9B (x), for example.

In a further exemplary step S811 of the method according to FIG. 8 (e.g. analogous to S109 in FIG. 1), the layer structure is opened on the rear side, in particular to expose the functional layer 3 on the side opposite the piezoelectric layer 4; see also FIG. 9B (xi), in which the substrate layer 1 and the intermediate layer 2 are opened on the rear side towards the functional layer 3, for example.

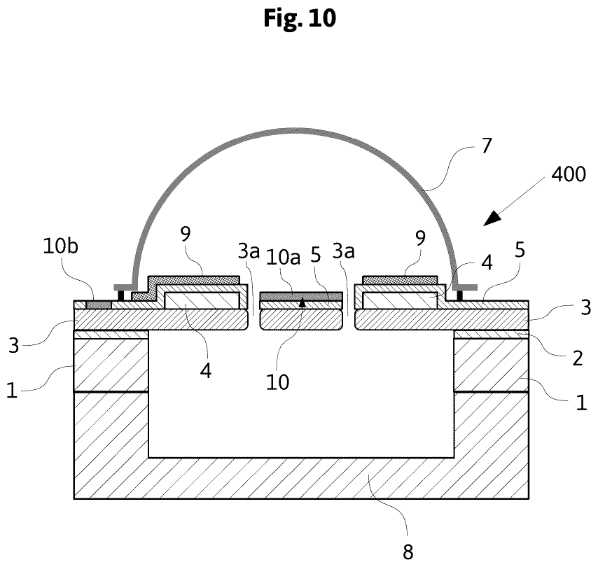

In a further exemplary step S812 of the method according to FIG. 8 (e.g. analogous to S110 in FIG. 1), the manufactured layer structure is provided in a vacuum-packed MEMS apparatus 400 according to FIG. 10. Here, for example, the layered structure was hermetically sealed from above with a translucent cover element 7 (e.g. a translucent dome element or a glass dome) and hermetically sealed from below with a base body element 8 in a vacuum atmosphere (e.g. vacuum encapsulation).

In some exemplary embodiments, differently shaped cover elements or 3D-shaped cover elements are also possible (e.g. angular or planar). The material of the cover elements is preferably translucent, e.g. glass or other optically transparent materials (e.g. approx. 400-2500 nm), such as borosilicate glass (e.g. Borofloat® BF33 by SCHOTT).

FIG. 10 shows an exemplary cross-sectional view of a MEMS apparatus 400 fabricated according to the exemplary fabrication sequence of FIGS. 9A-9B. Consequently, a vacuum-packed MEMS mirror device 400 (e.g., a MEMS mirror scanner) comprising the fabricated layered structure may be provided, e.g., with piezoelectrically deflectable or steerable mirrors 10a, wherein the corresponding layered structure or MEMS apparatus 400 comprising the layered structure conveniently has smoothened or smooth and/or crystal defect-free side walls and rounded corners at the structured regions and trenches of the functional layer, so that fracture limits of the moving or oscillating parts of the functional layer or, in particular, of the spring structure formed in the functional layer can be significantly increased and the occurrence of premature fractures of the spring structure can be successfully reduced. Compared to prior art methods without a curing step, the fracture limits of the moving or oscillating parts of the functional layer or, in particular, of the spring structure formed in the functional layer can be at least doubled or even increased fivefold or tenfold according to some exemplary embodiments with a curing step. Compared to the state of the art, i.e. when components are manufactured without cured side walls (i.e. in particular without smoothened side walls and/or without rounded corners) and fractures can occur in particular at smaller deflection angles or deflection amplitudes, the occurrence of fractures of the deflection structures or the spring structure can be significantly reduced and, in particular, larger deflection angles or deflection amplitudes can also be made possible, at which larger deflection angles or deflection amplitudes fractures of the deflection structures or the spring structure would already occur in components manufactured according to the state of the art.

FIG. 11 shows an exemplary flow diagram of a process for manufacturing a layered structure for a MEMS apparatus according to some further exemplary embodiments of the present disclosure.

However, the first steps of the method according to FIG. 11 initially correspond again, by way of example, to steps S101 to S103 of the method according to FIG. 1.

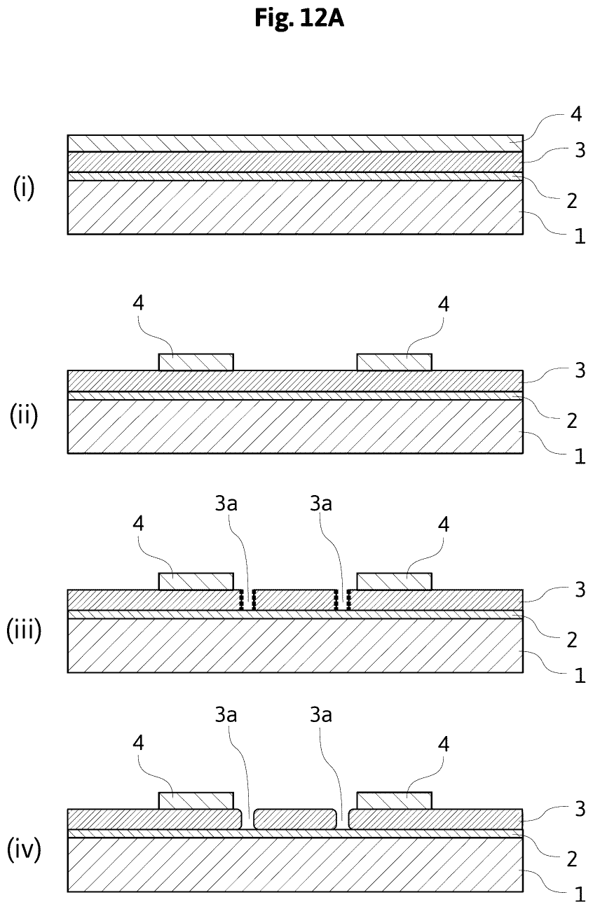

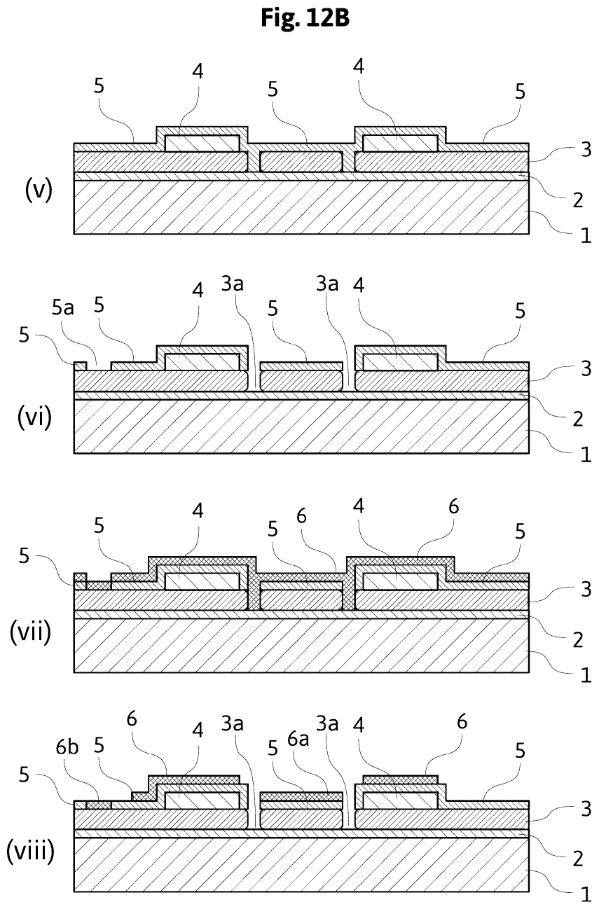

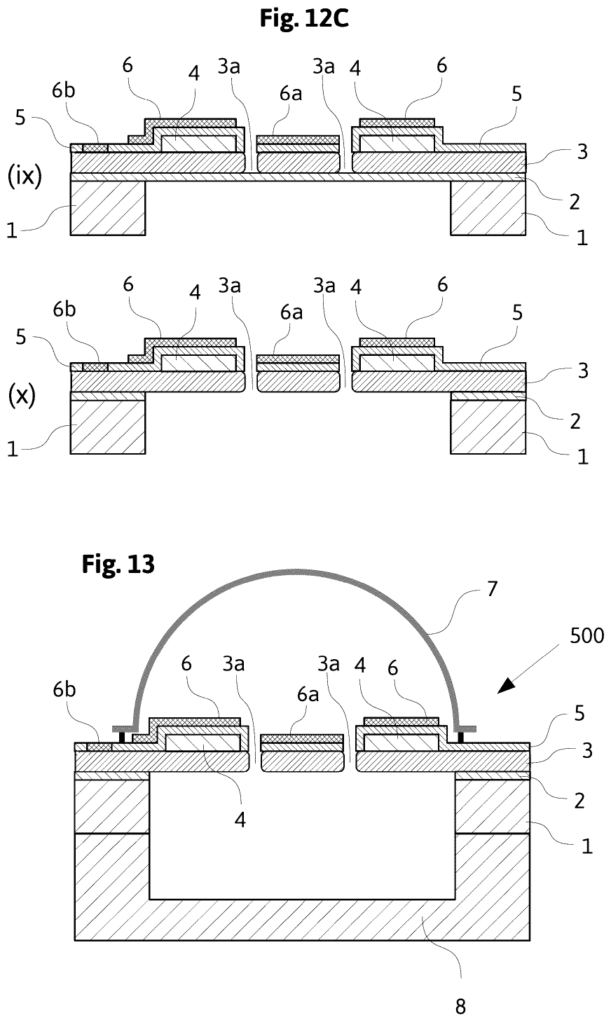

FIGS. 12A-12B show exemplary sectional views of the layer structure during the manufacturing process according to an exemplary manufacturing sequence based on the process according to FIG. 11.

With reference to FIG. 11 and FIG. 12A (i) to (iii), in an exemplary step S1101 (e.g. analogous to S101 in FIG. 1), the layer structure is provided, which exemplarily comprises the substrate layer 1 and the functional layer 3. In exemplary step S1102 (e.g. analogous to S102 in FIG. 1), the piezoelectric layer 4 is applied to the functional layer 3. In the further exemplary step S1103 (e.g. analogous to S103 in FIG. 1), the piezoelectric layer 4, which is applied on or above the functional layer 3, is structured as an example.

Furthermore, all descriptions of steps S301 to S303 from above are also applicable, by way of example, to the manufacturing sequence according to FIGS. 12A-12C in connection with steps S1101 to S1104 according to FIG. 11.

In contrast to the exemplary embodiments described above, the functional layer 3 is now structured directly (step S1104 of FIG. 11) according to some exemplary embodiments according to FIG. 11 before the dielectric layer 5 is applied and then, for example, the curing step S1105 takes place in a state of the layer structure in which structured regions of the piezoelectric layer 4 are open at the top

Accordingly, preferably in some exemplary embodiments, a piezoelectric layer 4 comprising a high-temperature-stable and/or chemically resistant piezoelectric material may be applied in step S1102. In some preferred exemplary embodiments, the high-temperature-stable and/or chemically resistant piezoelectric layer 4 may comprise, for example, aluminum nitride (AlN) and/or aluminum scandium nitride (AlScN).

In a further exemplary step S1104 of the method according to FIG. 11 (e.g. analogous to step S108 in FIG. 1), the functional layer 3 is structured in regions 3a, see also FIG. 12A (iii). In particular, the mechanically effective structures of the MEMS apparatus are formed in the functional layer, preferably by high-rate etching or deep reactive ion etching (DRIE for short). Structuring the functional layer 3 comprises, for example, forming or exposing the mirror support element (under the subsequently applied mirror layer 6a, see e.g. FIG. 13), which is formed from the functional layer 3 by way of example, and the holding webs (spring structure), which are formed from the functional layer 3 by way of example and can act as a holding spring structure,, and which can hold the mirror support element so that it can oscillate about one, two or more oscillation and/or torsion axes. In some exemplary embodiments, the spring structure may comprise springs, in particular preferably bending and/or torsion springs, which are preferably designed to hold the mirror support element such that the mirror support element can perform an oscillating rotational movement about the respective oscillation and/or torsion axis about the corresponding axis (e.g. torsional oscillations).

In some exemplary embodiments, the reactive ion depth etching for structuring the functional layer 3 can be performed using a photolithography mask, for example.

In the further exemplary step S1105 of the method according to FIG. 11 (e.g. analogous to S307 in FIG. 3), also in the manufacturing sequence according to FIGS. 12A-12C, an exemplary curing step is carried out at high temperatures substantially greater than or equal to 700° C., in particular to smooth the side walls of the regions 3a of the functional layer 3 that are depth-etched in step S1104 and to round off corners of the regions 3a of the functional layer 3.

In some exemplary embodiments, the curing step S1105 may comprise a step of oxidizing the surface of the regions 3a of the functional layer 3 at temperatures substantially greater than or equal to 700° C., preferably at temperatures substantially greater than or equal to 800° C. (e.g., at about 800° C. to 1250° C.). By way of example, after structuring S1104 of the functional layer 3, a sacrificial oxidation can be carried out as a curing step according to S1105.

This oxidation can oxidize the surface effects created during etching (e.g. unevenness, such as formed noses, waves, so-called scallops, as well as any other surface defects, such as crystal defects, etching, sidewall breakthroughs and atomic defects, etc.) on the sidewalls of the depth-etched sidewalls of the regions 3a of the functional layer 3. After the sacrificial oxidation, the sacrificial oxidation layer can preferably be selectively removed and, in particular, any etch scallops as well as any surface defects (e.g. crystal defects, etchings, sidewall breakthroughs and atomic defects, etc.) can be reduced or eliminated, so that smoothened sidewalls are formed, up to the complete transformation into a completely smooth and/or crystal defect-free sidewall. In addition, the right-angled structural corners that were created during the structuring of the functional layer can be rounded off (round or rounded structural corners). In some exemplary embodiments of the curing step S1105, after selective removal of the sacrificial oxidation layer 11, conveniently smoothened side walls and rounded structural corners of the side walls of the regions 3a of the functional layer 3 consequently remain; see, for example, FIG. 12A (iv).

In some exemplary embodiments, the curing step S1105 may again comprise (alternatively or in addition to the surface oxidation) a step in which the surface of the regions 3a of the functional layer 3 is subjected to a hydrogen annealing step, e.g. at temperatures substantially greater than or equal to 1000° C., e.g. from about 1000° C. to 1250° C. For example, after structuring S1104 of the functional layer 3 as a curing step according to S1105, the surface of the regions 3a of the functional layer 3, e.g. at temperatures substantially greater than or equal to 1000° C., e.g. from about 1000° C. to 1250° C., can thus be subjected to a hydrogen annealing step.

The hydrogen annealing or curing step results in smooth side walls and rounded corners on the surface of the regions 3a of the functional layer 3. In particular, any etching scallops as well as any surface defects (e.g. crystal defects, etching, sidewall breakthroughs and atomic defects, etc.) can be reduced or eliminated, so that smoothened sidewalls are formed, up to complete transformation into a completely smooth and/or crystal defect-free sidewall; see e.g. FIG. 12A (iv).

In some exemplary embodiments of the curing step S1105, the surface effects or surface defects (e.g. sidewall breakthroughs and atomic defects, or also formed noses, waves, so-called scallops, etc.) on the sidewalls of the depth-etched sidewalls of the regions 3a of the functional layer 3 can be smoothened by curing, e.g. by oxidation or sacrificial oxidation and/or by hydrogen annealing (analogous to S307 according to FIG. 3). After the curing step S1105, conveniently smoothened side walls of the regions 3a of the functional layer 3 with rounded corners remain; see e.g. FIG. 12A (iv).

After the corresponding curing step S1105, the corresponding layer structure or the MEMS apparatus comprising the layer structure has conveniently smoothened or smooth and/or crystal defect-free side walls and rounded corners at the structured regions and trenches of the functional layer, so that fracture limits of the moving or oscillating parts of the functional layer or in particular of the spring structure formed in the functional layer can be significantly increased and the occurrence of premature fractures of the spring structure can be successfully reduced. Compared to methods in the prior art without a curing step, the fracture limits of the moving or oscillating parts of the functional layer or, in particular, of the spring structure formed in the functional layer can be at least doubled or even increased fivefold or tenfold according to some exemplary embodiments with a curing step. Compared to the state of the art, i.e. when components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be significantly reduced and, in particular, larger deflection angles or deflection amplitudes can also be made possible, at which larger deflection angles or deflection amplitudes fractures of the deflection structures or the spring structure would already occur in components manufactured according to the state of the art.

In a further exemplary step S1106 of the method according to FIG. 11, a dielectric layer 5 is applied by way of example; see also FIG. 12B (v). According to FIG. 12B (v), the dielectric layer 5 is applied, by way of example, to regions of the piezoelectric layer 4 and furthermore, by way of example, to regions of the functional layer 3 which are open after structuring of the piezoelectric layer 4.

In some exemplary embodiments, the applied dielectric layer 5 can be opened in selected regions (step S1107 according to FIG. 11). For example, according to FIG. 12B (vi), in region 5b, the dielectric layer 5 is opened towards the functional layer 3 to provide a region 5b that may be provided for a subsequent bond pad. In some exemplary embodiments, the applied dielectric layer 5 can also be opened or partially opened over the structured regions of the piezoelectric layer 4.

In a further exemplary step S1108 of the method, an electrode layer 6 is applied by way of example to the dielectric layer 5, which was optionally previously opened in regions; see also FIG. 12B (vii). Here, for example, the region 5b that was previously opened in the dielectric layer 5, in particular to form a bond pad, and opened regions 3a of the trenches of the functional layer 3 are at least partially filled with the material of the electrode layer 6.

In a further exemplary step S1109 of the method according to FIG. 11, the electrode layer 6, which is applied on or above the dielectric layer 5, is structured as an example; see also FIG. 12B (viii). In the region 5b that is open in the dielectric layer 5, a bond pad 6b is formed with the material of the electrode layer, which provides an electrical contact to the upper side of the functional layer 3. In addition, any material of the electrode layer 6 can be removed from the open regions 3a of the trenches of the functional layer 3.

In the exemplary step S1109 of structuring the electrode layer 6, the desired structure of the upper electrode (top electrode) for the upper electrical contacting of the piezoelectric layer 4 is formed. Furthermore, in the exemplary step S1109 of structuring the electrode layer 6, for example in the center of the layer structure, according to FIG. 12B (viii), a mirror 6a (mirror layer with reflective surface) is formed by the material of the electrode layer 6.

In such examples, for example, the electrode layer may comprise metal, in particular aluminum, so that the surface of the electrode layer 6 already has a reflective surface and is suitable for forming the mirror 6a. In further examples, it is possible to provide a non-reflective or a non-metallic electrode layer (e.g. doped polycrystalline silicon), in which case a further, for example metallic mirror layer (e.g. as a thin-layer metal film, e.g. with a layer thickness of substantially greater than or equal to 100 nm and/or substantially less than or equal to 2000 nm) can be applied in the region of the layer 6a.

In some preferred exemplary embodiments, the material of the metallic mirror layer can be selected depending on the desired application for the respective wavelength range, in particular with very good reflection behavior in the wavelength range of the desired application, for example aluminum or silver for visible light (e.g. substantially at wavelengths of 400-700 nm) or gold for infrared light or infrared radiation (e.g. substantially at wavelengths of 850-2000 nm).

In a further exemplary step S1110 of the method according to FIG. 11, the layer structure is exemplarily opened at the rear, in particular to expose the functional layer 3 on the side opposite the piezoelectric layer 4; see also FIG. 12C (ix), in which the substrate layer 1 is exemplarily opened at the rear towards the intermediate layer 2, and FIG. 12C (x), in which the intermediate layer 2 is exemplarily opened at the rear towards the functional layer 3.

In a further exemplary step S1111 of the method according to FIG. 11, the manufactured layer structure is provided in a vacuum-packed MEMS apparatus 500 according to FIG. 13. Here, by way of example, the layered structure was hermetically sealed from above with a translucent cover element 7 (e.g. a translucent dome element or a glass dome) and from below with a base body element 8 under a vacuum atmosphere (e.g. vacuum encapsulation). In some further exemplary embodiments, differently shaped cover elements or 3D-shaped cover elements are also possible (e.g. angular or planar). The material of the cover elements is preferably translucent, e.g. glass or other optically transparent materials (e.g. approx. 400-2500 nm), such as borosilicate glass (e.g. Borofloat® BF33 by SCHOTT).

In the above exemplary embodiments, in particular steps S1106 and S1107 can be carried out analogously to steps S304 and S305 and corresponding descriptions to FIG. 3 and the associated exemplary manufacturing sequences can be applicable by way of example. In addition, steps S1108 to S1111 in particular can be carried out analogously to steps S308 to S311 and corresponding descriptions of FIG. 3 and the associated exemplary manufacturing sequences can be applicable by way of example.

FIG. 13 shows an exemplary sectional view of a MEMS apparatus 500 fabricated according to the exemplary fabrication sequence of FIGS. 12A-12C. Consequently, a vacuum-packed MEMS mirror device 500 (e.g., a MEMS mirror scanner) comprising the fabricated layered structure may be provided, in particular with piezoelectrically deflectable or controllable mirrors 6a, wherein the corresponding layered structure or MEMS apparatus 500 comprising the layered structure conveniently has smoothened or smooth and/or crystal defect-free sidewalls and rounded corners at the structured regions and trenches of the functional layer, so that fracture limits of the moving or oscillating parts of the functional layer or in particular of the spring structure formed in the functional layer can be significantly increased and the occurrence of premature fractures of the spring structure can be successfully reduced. Compared to prior art methods without a curing step, the fracture limits of the movable or oscillating parts of the functional layer or, in particular, of the spring structure formed in the functional layer can be at least doubled or even increased fivefold or tenfold according to some exemplary embodiments with a curing step. Compared to the state of the art, i.e. when components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be significantly reduced and, in particular, larger deflection angles or deflection amplitudes can also be made possible, at which larger deflection angles or deflection amplitudes fractures of the deflection structures or the spring structure would already occur in components manufactured according to the state of the art.

Above, some exemplary embodiments have been described which, based on the prior art, are capable of providing improved methods for manufacturing a layered structure for a MEMS apparatus, in particular in order to be able to provide the MEMS apparatus comprising the layered structure with higher mechanical breaking limits of the mechanically acting components of the layered structure or lower susceptibility to breakage.

Particularly conveniently, providing a layered structure according to some exemplary embodiments with structured regions of the piezoelectric layer encapsulated under a high-temperature-stable layer (e.g. under a dielectric layer) enables the integration of one or more high temperature curing steps (such as hydrogen annealing of deep etched surfaces, e.g. at about 1000° C.-1250° C., and/or sacrificial oxidation, e.g. at about 800° C.-1250° C., with etching back of the sacrificial oxide layer), even if less high-temperature-stable and/or less chemically resistant materials are used under the encapsulation (e.g. for any bottom electrode and/or for the piezoelectric layer, e.g. PZT). In some further exemplary embodiments, high-temperature-stable and/or more chemically resistant materials can also be used for the bottom electrode and/or for the piezoelectric layer, so that such curing steps can also be carried out without encapsulation.

In particular, it was found that the integration of a high-temperature curing step according to some exemplary embodiments (e.g. by hydrogen annealing and/or by a sacrificial oxidation according to some exemplary embodiments) successfully and conveniently enables the depth-etched sidewalls of the structured functional layer to be smoothened in order to remove the defects and roughness (e.g. scallops, sidewall breakthroughs and atomic defects, etc.) on the surface that were created during the etching process (e.g. DRIE). The surface of the structured functional layer can be smoothened to remove the defects and roughness (e.g. scallops, sidewall breakthroughs and atomic defects, etc.) created during the etching process (e.g. DRIE) and also to round off right-angled corners created during etching.

In particular, it was found that roughness values of up to 200 nm and generally over 50 nm each usually occur on the depth-etched side walls of the structured functional layer, which could be significantly smoothened to roughness values below about 50 nm (in particular less than or equal to 50 nm) by curing according to the above exemplary embodiments (e.g. by hydrogen annealing and/or by sacrificial oxidation according to some exemplary embodiments) could be significantly smoothened to roughness values below approx. 50 nm (in particular less than or equal to 50 nm), in particular to roughness values less than or equal to 30 nm, in particular less than or equal to 10 nm up to approx. less than or equal to 2-3 nm. In addition, the 90° corners on the depth-etched side walls of the structured functional layer could be rounded (finite corner radius).

According to some exemplary embodiments, this conveniently leads to a significantly increased stability or fracture resistance of the movable elements of the MEMS apparatus and in particular of the spring structure, which is formed from the functional layer, with increased fracture limits, whereby premature fractures of the spring structure or fractures of the spring structure at small deflection angles can be avoided.

Compared to prior art methods without a curing step, according to some exemplary embodiments with a curing step, the fracture limits of the moving or oscillating parts of the functional layer or in particular of the spring structure formed in the functional layer can be at least doubled, or even increased fivefold or tenfold. Compared to the state of the art, i.e. when components are manufactured without cured side walls (i.e. in particular without smoothened side walls and/or without rounded corners), in which fractures can occur in particular at smaller deflection angles or deflection amplitudes, the occurrence of fractures of the deflection structures or the spring structure can be significantly reduced and, in particular, larger deflection angles or deflection amplitudes can also be made possible, at which larger deflection angles or deflection amplitudes fractures of the deflection structures or the spring structure would already occur in components manufactured according to the state of the art.

In particular, conveniently, the layer structure according to some exemplary embodiments with conveniently smoothened side walls of the regions 3a of the functional layer 3 with rounded corners has increased load-bearing capacity and stability or fracture stability. It has been demonstrated that the layers of the layered structure, including the functional layer 3 with conveniently smoothened side walls and rounded corners, result in the functional layer having improved breaking limits.

In particular, the original fracture behavior, e.g. of silicon, can be restored by smoothing/curing the side walls or curing the side wall damage and rounding the corners, i.e. for example with a high modulus of elasticity (>160 GPa) and a high hardness (˜10 GPa), so that fracture limits can be significantly increased compared to the state of the art without curing. In particular, it has been demonstrated that the fracture limits can be increased from approx. 0.5-1.5 GPa to over 3 GPa up to more than 5 GPa.

In some exemplary embodiments in which a vacuum-packed MEMS apparatus is provided, higher quality factors of at least greater than 1000 or greater than 10000 or greater than 20000 can be achieved by resonant oscillation operation in a vacuum (e.g. <1 mbar) (at least a factor of 5 or 10 greater than operation under room atmosphere (˜1 bar)).

It should also be noted that the higher mechanical breaking limits of the layered structure of the MEMS apparatus according to some exemplary embodiments further conveniently enable larger deflection amplitudes of the movable elements (e.g. scan amplitudes of the oscillating mirror surface) to be increased. Conveniently, the MEMS apparatus according to some exemplary embodiments can be dimensioned differently or smaller, i.e. with a more compact design, which in turn can enable significant cost savings. Due to the higher breaking limit, higher stress values can be conveniently avoided in the springs, which makes it conveniently possible to use shortened springs according to some further exemplary embodiments. This may mean, for example, that more space is conveniently available for the mirror plate while the chip size can remain the same, so that larger mirror plates can be made possible, enabling higher optical resolutions to be provided.

Above, some exemplary embodiments of layered structures with layers have been described. It should be noted that exemplary embodiments should not be understood to be limiting in the sense that no further intermediate layers can be present in further exemplary embodiments. On the contrary, in some further exemplary embodiments, further layers and/or intermediate layers may be provided and/or described layers may be omitted.

It should be noted that only some examples or some exemplary embodiments of the present disclosure and technical advantages have been described in detail above with reference to the accompanying drawings. However, the present disclosure is in no way limited or restricted to the above-described exemplary embodiments and their exemplary embodiment features or their described combinations, but further includes modifications of the described exemplary embodiments, in particular those which are encompassed by modifications of the features of the described examples or by combination or partial combination of individual or several of the features of the described examples within the scope of protection of the independent claims.

### LIST OF REFERENCE SIGNS

1 Substrate layer
2 Intermediate layer
3 Functional layer (Device Layer)
3a Trenches or structured regions of the functional layer
4 Piezoelectric layer
5 Dielectric layer
5a Open region of the dielectric layer
6 Electrode layer
6a Mirror
6b Bondpad
7 Cover element
8 Floor element or base body element
9 Electrode layer (high-temperature-stable)
11 Sacrificial oxide layer
10 Electrode layer or mirror layer
10a Mirror
10b Bondpad
100 MEMS apparatus
200 MEMS apparatus
300 MEMS apparatus
400 MEMS apparatus
500 MEMS apparatus

1. A method for manufacturing a layered structure for a MEMS apparatus, in particular a vacuum-packed MEMS mirror device, the method comprising:
providing a layered structure which comprises a substrate layer and a functional layer,
applying a piezoelectric layer, in particular on a side of the functional layer opposite the substrate layer,
structuring the piezoelectric layer to form structured regions of the piezoelectric layer,
structuring the functional layer to form structured regions of the functional layer, and
curing trenches in the structured regions of the functional layer at temperatures substantially greater than or equal to 700° C.

2. Method according to claim 1, characterized in that
the curing of structured regions of the functional layer is carried out for at least partial smoothening of side walls of the trenches in the functional layer and/or for rounding off corners of the trenches in the functional layer.

3. Method according to claim 1, characterized in that
the curing of structured regions of the functional layer is carried out at temperatures substantially greater than or equal to 800° C.

4. Method according to claim 1, characterized in that
the curing of structured regions of the functional layer is carried out at temperatures substantially less than or equal to 1400° C., in particular at temperatures substantially less than or equal to 1350° C.

5. Method according to claim 1, characterized in that
the curing of structured regions of the functional layer comprises hydrogen annealing.

6. Method according to claim 5, characterized in that
the hydrogen annealing is carried out at temperatures substantially greater than or equal to 900° C. and/or substantially less than or equal to 1350° C., in particular at temperatures substantially greater than or equal to 1000° C. and/or substantially less than or equal to 1250° C.

7. Method according to claim 1, characterized in that
the curing of structured regions of the functional layer comprises oxidizing side walls of the trenches in the functional layer.

8. Method according to claim 7, characterized in that
the oxidation of side walls of the trenches in the functional layer is carried out at temperatures substantially greater than or equal to 700° C., in particular at substantially greater than or equal to 800° C., and/or at substantially less than or equal to 1250° C.

9. Method according to claim 7, characterized in that
the curing of structured regions of the functional layer further comprises removing an oxidation layer formed on side walls of the trenches in the functional layer, in particular by etching.

10. Method according to claim 1, characterized by
applying an electrode layer after the curing of structured regions of the functional layer for forming an electrode structure for the structured regions of the piezoelectric layer and/or for forming a mirror and/or a mirror layer on one or more structured regions of the functional layer.

11. Method according to claim 1, characterized by
applying a high-temperature-stable electrode layer before the curing of structured regions of the functional layer to form an electrode structure for the structured regions of the piezoelectric layer.

12. Method according to claim 11, characterized in that
the material of the high-temperature-stable electrode layer comprises an electrically conductively doped silicon, in particular doped polycrystalline silicon.

13. Method according to claim 11, characterized in that
the material of the high-temperature-stable electrode layer comprises a high-temperature-stable metal, a high-temperature-stable metal alloy and/or a high-temperature-stable metal compound.

14. Method according to claim 13, characterized in that
the material of the high-temperature-stable electrode layer comprises platinum, molybdenum and/or a high-temperature-stable molybdenum alloy or molybdenum compound, tungsten or a high-temperature-stable tungsten alloy or tungsten compound, in particular tungsten titanium and/or tungsten carbide.

15. Method according claim 11, characterized in that
the high-temperature-stable electrode layer is applied and/or structured such that the structured regions of the piezoelectric layer are encapsulated between the functional layer and the high-temperature-stable electrode layer, optionally having an interposed dielectric layer or partially interposed dielectric layer.

16. Method according to claim 1, characterized by
applying a further layer after curing of structured regions of the functional layer to form a mirror and/or a mirror layer on one or more structured regions of the functional layer.

17. Method according to claim 1, characterized by
applying a dielectric layer at least on the structured regions of the piezoelectric layer before curing of structured regions of the functional layer and in particular before application of an electrode layer.

18. Method according to claim 17, characterized in that
the dielectric layer is applied such that the structured regions of the piezoelectric layer are encapsulated between the functional layer and the dielectric layer applied to the structured regions of the piezoelectric layer.

19. Method according to claim 17, characterized by
structuring and/or opening of regions of the dielectric layer during or before structuring of the functional layer.

20. Method according to claim 19, characterized in that
the dielectric layer is structured and/or opened in such a way that the structured regions of the piezoelectric layer remain encapsulated between the functional layer and the dielectric layer applied to the structured regions of the piezoelectric layer.

21. Method according to claim 1, characterized in that
the material of the piezoelectric layer comprises a ferro- and/or piezoelectric material, in particular aluminum nitride (AlN), aluminum scandium nitride (AlScN), lead zirconate titanate (PZT) and/or niobium-doped PZT (PZT-Nb)

22. Method according to claim 1, characterized by
applying a dielectric layer at least on the structured regions of the piezoelectric layer after curing of structured regions of the functional layer,
wherein the material of the piezoelectric layer comprises a ferro- and/or piezoelectric material which is stable at high temperatures, in particular aluminum nitride (AlN) and/or aluminum scandium nitride (AlScN).

23. Method according claim 1, characterized in that
the structured regions of the functional layer comprise one or more movable elements formed in the functional layer and/or a spring structure formed in the functional layer, wherein the spring structure in particular holds the one or more movable elements.

24. Method according to claim 23, characterized in that
the one or more movable elements of the structured regions of the functional layer comprise a mirror support element, wherein the mirror is arranged on the mirror support element.

25. Method according to claim 24, characterized in
the spring structure of the structured regions of the functional layer holds the mirror support element with a mirror and the spring structure in the functional layer is designed such that the mirror support element with the mirror is held so that it can oscillate about one or two axes, in particular oscillation and/or torsion axes, in particular preferably for a two-dimensional Lissajous scanning movement of the mirror support element with the mirror.

26. Method according to claim 1, characterized in that
the structuring of the functional layer comprises high-rate etching and/or reactive ion depth etching.

27. A layered structure manufactured by the method according to at claim 1, comprising:
a substrate layer,
a structured functional layer, and
a structured piezoelectric layer on a side of the functional layer opposite the substrate layer,
wherein trenches of the functional layer in structured regions of the functional layer are cured, and in particular the trenches having smoothened and/or crystal defect-free side walls and/or rounded corners.

28. Layered structure according to claim 27, characterized in that
a surface roughness of side walls of the trenches of the functional layer in structured regions of the functional layer is substantially less than or equal to 50 nm, in particular substantially less than or equal to 30 nm, in particular preferably less than or equal to 10 nm.

29. A MEMS apparatus, comprising a layered structure the layered structure comprising:
a substrate layer,
a structured functional layer, and
a structured piezoelectric layer on a side of the functional layer opposite the substrate layer,
wherein trenches of the functional layer in structured regions of the functional layer are cured, and in particular the trenches having smoothened and/or crystal defect-free side walls and/or rounded corners.
